(19) United States
(12) Patent Application Publication
(10) Pub. No.: US 2026/0190732 A1
(43) Pub. Date: Jul. 2, 2026

(54) DISPLAY DEVICE, ELECTRONIC DEVICE AND METHOD FOR FABRICATING DISPLAY DEVICE

(71) Applicant: Samsung Display Co., Ltd., Yongin-si (KR)

(72) Inventor: Chun Gi YOU, Yongin-si (KR)

(21) Appl. No.: 19/292,737

(22) Filed: Aug. 6, 2025

(30) Foreign Application Priority Data
Dec. 31, 2024 (KR) 10-2024-0201765

(51) Int. Cl. H10K 59/35; H10K 59/12; H10K 59/122; H10K 59/80; H10K 102/00

(52) U.S. Cl. CPC H10K 59/353; H10K 59/1201; H10K 59/122; H10K 59/80518; H10K 2102/351

(57) ABSTRACT

A display device, an electronic device including the display device, and a method for fabricating the display device are disclosed. The display device may include: a substrate including a first sub-pixel area and a second sub-pixel area; a reflective electrode in the first and second sub-pixel areas on the substrate; a first electrode on the substrate to be around (e.g., surround) the reflective electrode; a capping layer provided on the first electrode and having a first opening defined in the capping layer; a planarization layer provided on the capping layer and having a second opening defined in the planarization layer; a light emitting stack layer on the first electrode; and a second electrode on the light emitting stack layer, wherein the first electrode includes an upper electrode portion and a side electrode portion, and the capping layer includes an upper capping portion and a side capping portion.

### CROSS-REFERENCE TO RELATED APPLICATION

The present application claims priority to and the benefit of Korean Patent Application No. 10-2024-0201765, filed on Dec. 31, 2024, in the Korean Intellectual Property Office, the entire disclosure of which is incorporated herein by reference.

### BACKGROUND

### 1. Field

One or more embodiments of the present disclosure relate to a display device, an electronic device including the display device, and a method for fabricating the display device. For example, one or more embodiments of the present disclosure relate to a display device, an electronic device including the display device, and a method for fabricating the display device, which are capable of preventing damage (or reducing a degree or occurrence of damage) to a reflective electrode during a process.

### 2. Description of the Related Art

Organic light emitting display devices include a display element of which luminance is changed by current, for example, an organic light emitting diode.

A head mounted display (HMD) to which an organic light emitting display device is applied is an image display device that can be worn on a user's head in the form of glasses and/or helmets to form a focus at a close distance in front of the user's eyes. The head mounted display may implement virtual reality (VR) and/or augmented reality (AR).

The head mounted display magnifies an image displayed on a small display device by utilizing a plurality of lenses and displays the magnified image. Therefore, it is desirable for the display device applied to the head mounted display to provide high-resolution images, for example, images having a resolution of 3000 pixels per inch (PPI) or higher. To this end, an organic light emitting diode on silicon (OLEDoS), which is a high-resolution small organic light emitting display device, is used as the display device applied to the head mounted display. The OLEDoS is an image display device in which an organic light emitting diode (OLED) is on a semiconductor wafer substrate on which a complementary metal oxide semiconductor (CMOS) is provided.

### SUMMARY

One or more aspects of embodiments of the present disclosure are directed toward a display device, an electronic device including the display device, and a method for fabricating the display device, which are capable of preventing damage (or reducing a degree or occurrence of damage) to a reflective electrode during a process.

Additional aspects of embodiments will be set forth in part in the description which follows and, in part, will be apparent from the description or may be learned by practice of the presented embodiments of the disclosure.

According to one or more embodiments of the present disclosure, a display device includes: a substrate including a first sub-pixel area and a second sub-pixel area; a reflective electrode in the first sub-pixel area and the second sub-pixel area that are on the substrate; a first electrode on the substrate to be around (e.g., surround) the reflective electrode; a capping layer located or provided on the first electrode and having a first opening defined in the capping layer to overlap the first electrode; a planarization layer located or provided on the capping layer and having a second opening defined in the planarization layer to overlap the first opening; a light emitting stack layer on the first electrode; and a second electrode on the light emitting stack layer, wherein the first electrode includes an upper electrode portion on a top surface of the reflective electrode and a side electrode portion extending from the upper electrode portion to the substrate and located or provided on a side surface of the reflective electrode, the capping layer includes an upper capping portion on the upper electrode portion and a side capping portion on the side electrode portion, the side electrode portion in the first sub-pixel area is disconnected from the side electrode portion in the second sub-pixel area, and the side capping portion in the first sub-pixel area is disconnected from the side capping portion in the second sub-pixel area.

According to one or more embodiments of the present disclosure, an electronic device includes: a display device having a resolution of (or having) about 4,000 pixels per inch (PPI) or higher; an optical member outside the display device to control a path of light emitted from the display device; and a case to accommodate the display device and the optical member, wherein the display device includes: a substrate including a first sub-pixel area and a second sub-pixel area; a reflective electrode in the first sub-pixel area and the second sub-pixel area that are on the substrate; a first electrode on the substrate to be around (e.g., surround) the reflective electrode; a capping layer located or provided on the first electrode and having a first opening defined in the capping layer to overlap the first electrode; a planarization layer located or provided on the capping layer and having a second opening defined in the planarization layer to overlap the first opening; a light emitting stack layer on the first electrode; and a second electrode on the light emitting stack layer, wherein the first electrode includes an upper electrode portion on a top surface of the reflective electrode and a side electrode portion extending from the upper electrode portion to the substrate and located or provided on a side surface of the reflective electrode, the side electrode portion in the first sub-pixel area is disconnected from the side electrode portion in the second sub-pixel area, and the side capping portion in the first sub-pixel area is disconnected from the side capping portion in the second sub-pixel area.

According to one or more embodiments of the present disclosure, a method for fabricating a display device includes: preparing a substrate having an insulating (e.g., electrically insulating) layer and a via electrode penetrating the insulating layer formed or provided on the substrate; forming or providing a reflective electrode and a resonance control layer that are sequentially stacked on the via electrode; forming or providing a first preliminary electrode on the insulating layer to be around (e.g., surround) the reflective electrode and the resonance control layer; forming or providing a first preliminary capping layer on the first preliminary electrode; forming or providing a first photoresist pattern on the first preliminary capping layer; and etching the first preliminary capping layer and the first preliminary electrode together utilizing the first photoresist pattern as a mask (e.g., a first mask) to form or provide a second preliminary capping layer and a first electrode, respectively, and exposing a part of the insulating layer.

According to one or more embodiments, damage to a reflective electrode may be prevented (or a degree or occurrence of damage to a reflective electrode may be reduced) during a process.

For example, according to one or more embodiments, a first electrode and a capping layer may be concurrently (e.g., simultaneously) patterned and formed or provided, so that (e.g., such that) the first electrode may be surrounded by the capping layer. Therefore, the path for hydrogen fluoride to permeate into the reflective electrode may be blocked by the capping layer. Therefore, damage to the reflective electrode including an aluminum material (e.g., a material including aluminum) may be prevented (or a degree or occurrence of damage to the reflective electrode including an aluminum material (e.g., a material including aluminum) may be reduced) by hydrogen fluoride.

However, aspects and features of embodiments of the present disclosure are not restricted to the one set forth herein. The above and other aspects and features of certain embodiments of the present disclosure will become more apparent to one of ordinary skill in the art to which the present disclosure pertains by referencing the detailed description of the present disclosure given.

### BRIEF DESCRIPTION OF THE DRAWINGS

The above and other aspects and features of certain embodiments of the present disclosure will become more apparent from the following description taken in conjunction with the accompanying drawings, in which:

FIG. 1 is an exploded perspective view illustrating a display device according to one or more embodiments;

FIG. 2 is a block diagram illustrating a display device according to one or more embodiments;

FIG. 3 is an equivalent circuit diagram of a first sub-pixel area according to one or more embodiments;

FIG. 4 is a layout diagram illustrating an example of a display panel according to one or more embodiments;

FIGS. 5 and 6 are layout diagrams illustrating examples of the display area of FIG. 4;

FIG. 7 is a cross-sectional view illustrating an example of a display panel taken along the line I1-I1′ of FIG. 5;

FIG. 8 is a cross-sectional view illustrating the area A1 of FIG. 7 in more detail;

FIG. 9 is a cross-sectional view illustrating the area A2 of FIG. 8 in more detail;

FIGS. 10-26 are process views illustrating a method for fabricating a display device according to one or more embodiments;

FIG. 27 is a block diagram of an electronic device according to one or more embodiments;

FIGS. 28-30 are schematic diagrams illustrating electronic devices according to one or more embodiments; and

FIG. 31 is a perspective view illustrating a head mounted display according to one or more embodiments.

### DETAILED DESCRIPTION

The subject matter of the present invention will be described more fully hereinafter with reference to the accompanying drawings, in which embodiments of the present disclosure are shown. The subject matter of the present disclosure may, however, be embodied in different forms and should not be construed as being limited to one or more embodiments set forth herein. Rather, these embodiments are provided as examples so that this disclosure will be thorough and complete and will fully convey the aspects and features of the present disclosure to those skilled in the art.

The utilization of “may” if (e.g., when) describing embodiments of the present disclosure refers to “one or more embodiments of the present disclosure.”

In the context of the present disclosure and unless otherwise defined, the terms, “use,” “using,” and “used,” may be considered synonymous with the terms, “utilize,” “utilizing,” and “utilized,” respectively.

As used herein, the term, “and/or,” includes any and all combinations of one or more of the associated listed items. For example, “A and/or B” indicates cases where it is A, B, or both (e.g., simultaneously) A and B.

Throughout the present disclosure, the expression, “at least one of a, b, or c,” indicates only a, only b, only c, both (e.g., simultaneously) a and b, both (e.g., simultaneously) a and c, both (e.g., simultaneously) b and c, all of a, b, and c, or variations thereof.

The singular forms, “a,” “an,” and “the,” include plural references unless the context clearly requires otherwise.

In the present disclosure, it will be understood that the term “comprise(s)/comprising,” “include(s)/including,” or “have/has/having” specifies the presence of stated features, integers, steps, operations, elements, and/or components, but do not preclude the presence or addition of one or more other features, integers, steps, operations, elements, components, and/or groups thereof. Also, the terms “comprise(s)/comprising,” “include(s)/including,” “have/has/having,” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

It will also be understood that if (e.g., when) a layer is referred to as being “on” or “above” another layer or substrate, it may be directly on or directly above the other layer or substrate, or intervening layers may also be present therebetween. In contrast, if (e.g., when) a layer is referred to as being “directly on” or “directly above” another layer or substrate, there are no intervening layers present therebetween.

The same reference numerals indicate substantially the same components throughout the specification. In the accompanying drawings, the thickness of layers and regions may be exaggerated for clarity.

Although the terms, “first”, “second”, and/or the like, may be used herein to describe one or more suitable elements, these elements should not be limited by these terms. These terms may be used to distinguish one element from another element. Thus, a first element as described in one or more embodiments may be termed a second element without departing from the scope of the present disclosure. The description of an element as a “first” element may not require or imply the presence of a second element or other elements. The terms, “first”, “second”, and/or the like, may also be used herein to differentiate different categories or sets of elements. For conciseness, the terms, “first”, “second”, and/or the like, may represent “first-category (or first-set)”, “second-category (or second-set)”, and/or the like, respectively.

The features of one or more embodiments of the present disclosure may be combined partially or totally. As will be clearly appreciated by those skilled in the art, one or more suitable interactions and operations may be feasible. One or more suitable embodiments may be practiced individually or in combination.

As used herein, the terms, “substantially,” “about,” and/or the like, are used as terms of approximation and not as terms of degree and are intended to account for the inherent deviations in measured or calculated values that would be recognized by those of ordinary skill in the art.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in the present disclosure is intended to include all higher numerical limitations subsumed therein. Accordingly, Applicant reserves the right to amend this specification, including the claims, to expressly recite any sub-range subsumed within the ranges expressly recited herein.

In the context of the present disclosure and unless otherwise defined, plan view is an orthographic projection of a three-dimensional object from the position of a horizontal plane that intersects the object. For example, it is a top-down view, illustrating the layout and spatial relationships of one or more elements within the object or structure. A plan view based on a z-axis (thickness) direction refers to a top-down view of the object, as if (e.g., when) looking directly down onto the surface from above. In this context, the z-axis direction is perpendicular or normal to the horizontal plane defined by x-axis and y-axis directions.

Hereinafter, one or more embodiments of the present disclosure will be described in more detail with reference to the accompanying drawings.

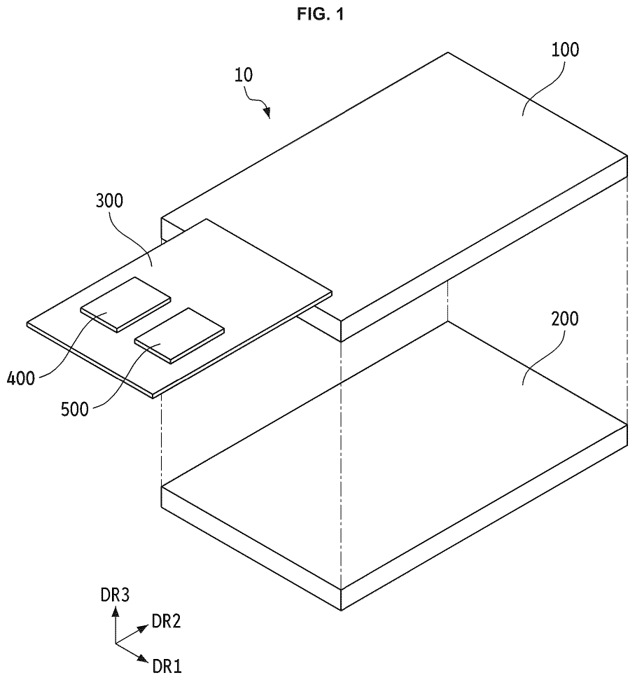

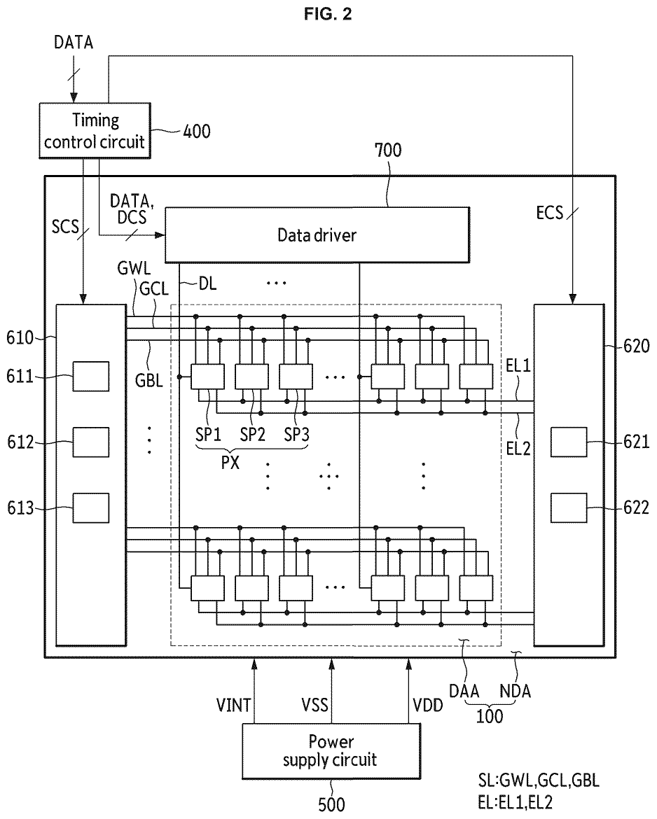

FIG. 1 is an exploded perspective view illustrating a display device according to one or more embodiments. FIG. 2 is a block diagram illustrating a display device according to one or more embodiments.

Referring to FIGS. 1 and 2, a display device 10 according to one or more embodiments may be a device to display a moving image and/or a still image. The display device 10 according to one or more embodiments may be applied to portable electronic devices, such as a mobile phone, a smartphone, a tablet personal computer, a mobile communication terminal, an electronic organizer, an electronic book, a portable multimedia player (PMP), a navigation system, an ultra mobile PC (UMPC), and/or the like. For example, the display device 10 according to one or more embodiments may be applied as a display unit of a television, a laptop, a monitor, a billboard, and/or an internet-of-things (IoT) terminal. In one or more embodiments, the display device 10 according to one or more embodiments may be applied to a smart watch, a watch phone, a head mounted display (HMD) to implement virtual reality and/or augmented reality, and/or the like.

A display device according to one or more embodiments may have a resolution of, for example, about 4,000 PPI or higher.

The display device 10 according to one or more embodiments may include a display panel 100, a heat dissipation layer 200, a circuit board 300, a timing control circuit 400, and a power supply circuit 500.

The display panel 100 may have a planar shape (e.g., a substantially planar shape) similar to a quadrilateral shape (e.g., a substantially quadrilateral shape). For example, the display panel 100 may have a planar shape (e.g., a substantially planar shape) similar to a quadrilateral shape (e.g., a substantially quadrilateral shape), having a short side of a first direction DR1 and a long side of a second direction DR2 crossing (e.g., intersecting) the first direction DR1. In the display panel 100, a corner where a short side in the first direction DR1 and a long side in the second direction DR2 meet may be right-angled or rounded with a selected (e.g., set or predetermined) curvature. The planar shape of the display panel 100 is not limited to a quadrilateral shape (e.g., a substantially quadrilateral shape) and may be a shape similar to another polygonal shape (e.g., a substantially polygonal shape), a circular shape (e.g., a substantially circular shape), or an elliptical shape (e.g., a substantially elliptical shape). The planar shape of the display device 10 may conform to the planar shape of the display panel 100, but embodiments of the present disclosure are not limited thereto.

The display panel 100 may include a plurality of pixels PX, a plurality of scan lines SL, a plurality of emission control lines EL, a plurality of data lines DL, a scan driver 610, an emission driver 620, and a data driver 700. The display panel 100 may be divided into a display area DAA to display an image and a non-display area NDA not to display an image (e.g., the image and/or an other image) as illustrated in FIG. 2.

The plurality of pixels PX may be in the display area DAA. The plurality of pixels PX may be arranged or provided in a matrix form in the first direction DR1 and the second direction DR2. The plurality of scan lines SL and the plurality of emission control lines EL may extend in the first direction DR1, while being arranged or provided in the second direction DR2. The plurality of data lines DL may extend in the second direction DR2, while being arranged or provided in the first direction DR1.

The plurality of scan lines SL may include a plurality of write scan lines GWL, a plurality of control scan lines GCL, and a plurality of bias scan lines GBL. The plurality of emission control lines EL may include a plurality of first emission control lines EL1 and a plurality of second emission control lines EL2.

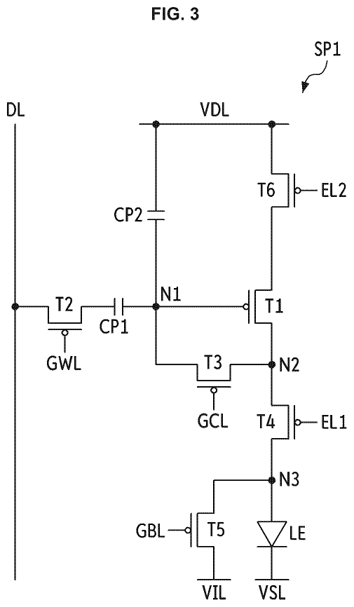

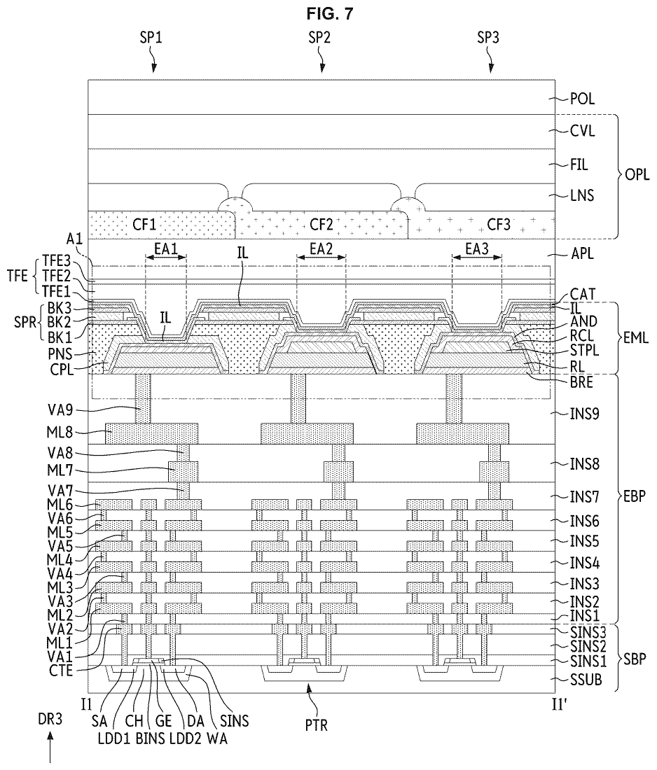

The plurality of pixels PX may include a plurality of sub-pixel areas SP1, SP2, and SP3. The plurality of sub-pixel areas SP1, SP2, and SP3 may include a plurality of pixel transistors as illustrated in FIG. 3, and the plurality of pixel transistors may be formed or provided by a semiconductor process and located or provided on a semiconductor substrate SSUB (see FIG. 7). For example, the plurality of pixel transistors of the data driver 700 may be formed or provided as complementary metal oxide semiconductor (CMOS) transistors, but embodiments of the present disclosure are not limited thereto.

Each of the plurality of sub-pixel areas SP1, SP2, and SP3 may be connected to any one write scan line GWL selected from among the plurality of write scan lines GWL, any one control scan line GCL selected from among the plurality of control scan lines GCL, any one bias scan line GBL selected from among the plurality of bias scan lines GBL, any one first emission control line EL1 selected from among the plurality of first emission control lines EL1, any one second emission control line EL2 selected from among the plurality of second emission control lines EL2, and any one data line DL selected from among the plurality of data lines DL. Each of the plurality of sub-pixel areas SP1, SP2, and SP3 may receive a data voltage of the data line DL in response to a write scan signal of the write scan line GWL and emit light from the light emitting element according to the data voltage.

The scan driver 610, the emission driver 620, and the data driver 700 may be in the non-display area NDA.

The scan driver 610 may include a plurality of scan transistors, and the emission driver 620 may include a plurality of light emitting transistors. The plurality of scan transistors and the plurality of light emitting transistors may be formed or provided on the semiconductor substrate SSUB (see FIG. 7) through a semiconductor process. For example, the plurality of scan transistors and the plurality of light emitting transistors may be formed or provided as CMOS transistors, but embodiments of the present disclosure are not limited thereto.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing control circuit 400. The write scan signal output unit 611 may generate write scan signals according to the scan timing control signal SCS of the timing control circuit 400 and output them sequentially to the write scan lines GWL. The control scan signal output unit 612 may generate control scan signals in response to the scan timing control signal SCS and sequentially output them to the control scan lines GCL. The bias scan signal output unit 613 may generate bias scan signals according to the scan timing control signal SCS and output them sequentially to the bias scan lines GBL.

The emission driver 620 may include a first emission control driver 621 and a second emission control driver 622. Each of the first emission control driver 621 and the second emission control driver 622 may receive an emission timing control signal ECS from the timing control circuit 400. The first emission control driver 621 may generate first emission control signals according to the emission timing control signal ECS and sequentially output them to the first emission control lines EL1. The second emission control driver 622 may generate second emission control signals according to the emission timing control signal ECS and sequentially output them to the second emission control lines EL2.

The data driver 700 may include a plurality of data transistors, and the plurality of data transistors may be formed or provided on the semiconductor substrate SSUB (see FIG. 7) through a semiconductor process. For example, the plurality of data transistors may be formed or provided as CMOS transistors, but embodiments of the present disclosure are not limited thereto.

The data driver 700 may receive digital video data DATA and a data timing control signal DCS from the timing control circuit 400. The data driver 700 may convert the digital video data DATA into analog data voltages according to the data timing control signal DCS and output the analog data voltages to data lines DL. In this case, the sub-pixel areas SP1, SP2, and SP3 may be selected by the write scan signal of the scan driver 610, and data voltages may be supplied to the selected sub-pixel areas SP1, SP2, and SP3.

The heat dissipation layer 200 may overlap the display panel 100 in a third direction DR3, which is a thickness direction of the display panel 100. The heat dissipation layer 200 may be located or provided on one surface, e.g., the rear surface, of the display panel 100. The heat dissipation layer 200 may serve to dissipate heat generated from the display panel 100. The heat dissipation layer 200 may include a metal layer having high thermal conductivity, such as graphite, silver (Ag), copper (Cu), and/or aluminum (Al).

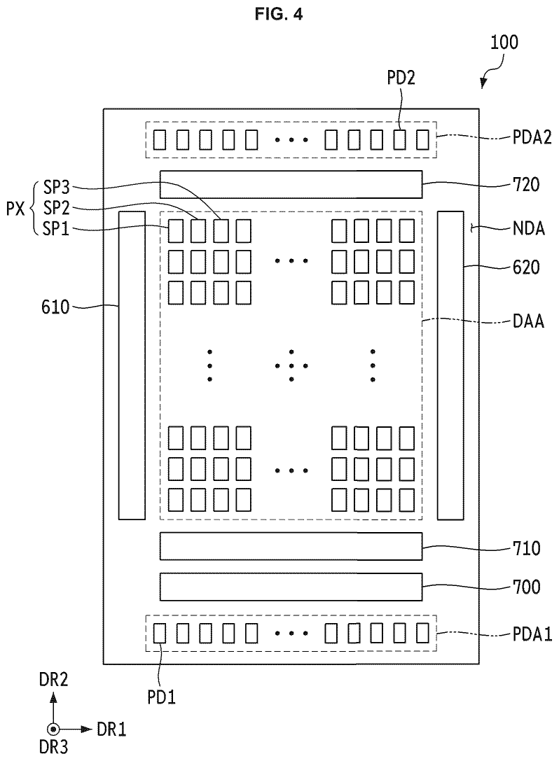

The circuit board 300 may be electrically connected to a plurality of first pads PD1 (see FIG. 4) of a first pad portion PDA1 (see FIG. 4) of the display panel 100 by utilizing a conductive (e.g., electrically conductive) adhesive member, such as an anisotropic conductive film. The circuit board 300 may be a flexible printed circuit board having a flexible material and/or a flexible film. Although the circuit board 300 is illustrated in FIG. 1 as being unfolded, the circuit board 300 may be bent. In this case, one end of the circuit board 300 may be located or provided on the rear surface of the display panel 100 and/or the rear surface of the heat dissipation layer 200. The other end of the circuit board 300 may be connected to the plurality of first pads PD1 (see FIG. 4) of the first pad portion PDA1 (see FIG. 4) of the display panel 100 by utilizing a conductive (e.g., electrically conductive) adhesive member. One end of the circuit board 300 may be an opposite end of the other end of the circuit board 300.

The timing control circuit 400 may receive digital video data and timing signals inputted from the outside. The timing control circuit 400 may generate the scan timing control signal SCS, the emission timing control signal ECS, and the data timing control signal DCS to control the display panel 100 in response to the timing signals. The timing control circuit 400 may output the scan timing control signal SCS to the scan driver 610 and output the emission timing control signal ECS to the emission driver 620. The timing control circuit 400 may output the digital video data and the data timing control signal DCS to the data driver 700.

The power supply circuit 500 may generate a plurality of panel driving voltages according to a power voltage from the outside. For example, the power supply circuit 500 may generate a first driving voltage VSS, a second driving voltage VDD, and a third driving voltage VINT and supply them to the display panel 100. The first driving voltage VSS, the second driving voltage VDD, and the third driving voltage VINT will be described herein in more detail in conjunction with FIG. 3.

Each of the timing control circuit 400 and the power supply circuit 500 may be formed or provided as an integrated circuit (IC) and attached to one surface of the circuit board 300. In this case, the scan timing control signal SCS, the emission timing control signal ECS, the digital video data DATA, and the data timing control signal DCS of the timing control circuit 400 may be supplied to the display panel 100 through the circuit board 300. Further, the first driving voltage VSS, the second driving voltage VDD, and the third driving voltage VINT of the power supply circuit 500 may be supplied to the display panel 100 through the circuit board 300.

In one or more embodiments, each of the timing control circuit 400 and the power supply circuit 500 may be in the non-display area NDA of the display panel 100, similarly to the scan driver 610, the emission driver 620, and the data driver 700. In this case, the timing control circuit 400 may include a plurality of timing transistors, and each power supply circuit 500 may include a plurality of power transistors. The plurality of timing transistors and the plurality of power transistors may be formed or provided on the semiconductor substrate SSUB (see FIG. 7) through a semiconductor process. For example, the plurality of timing transistors and the plurality of power transistors may be formed or provided as CMOS transistors, but embodiments of the present disclosure are not limited thereto. Each of the timing control circuit 400 and the power supply circuit 500 may be located or provided between the data driver 700 and the first pad portion PDA1 (see FIG. 4).

FIG. 3 is an equivalent circuit diagram of a first sub-pixel area according to one or more embodiments.

Referring to FIG. 3, the first sub-pixel area SP1 may be connected to the write scan line GWL, the control scan line GCL, the bias scan line GBL, the first emission control line EL1, the second emission control line EL2, and the data line DL. Further, the first sub-pixel area SP1 may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied. In one or more embodiments, the first driving voltage line VSL may be a low potential voltage line, the second driving voltage line VDL may be a high potential voltage line, and the third driving voltage line VIL may be an initialization voltage line. In this case, the first driving voltage VSS may be lower than the third driving voltage VINT. The second driving voltage VDD may be higher than the third driving voltage VINT.

The first sub-pixel area SP1 may include a plurality of transistors T1 to T6, a light emitting element LE, a first capacitor CP1, and a second capacitor CP2.

The light emitting element LE may emit light in response to a driving current that flows through the channel of the first transistor T1. The emission amount of the light emitting element LE may be proportional to the driving current Ids. The light emitting element LE may be located or provided between a fourth transistor T4 and the first driving voltage line VSL. The first electrode of the light emitting element LE may be connected to the drain electrode of the fourth transistor T4, and the second electrode of the light emitting element LE may be connected to the first driving voltage line VSL. The first electrode of the light emitting element LE may be an anode electrode, and the second electrode of the light emitting element LE may be a cathode electrode. The light emitting element LE may be an organic light emitting diode including a first electrode, a second electrode, and an organic light emitting layer between the first electrode and the second electrode, but embodiments of the present disclosure are not limited thereto. For example, the light emitting element LE may be an inorganic light emitting element including a first electrode, a second electrode, and an inorganic semiconductor between the first electrode and the second electrode, in which case the light emitting element LE may be a micro light emitting diode.

The first transistor T1 may be a driving transistor that controls a source-drain current Ids (hereinafter referred to as “driving current”) that flows between the source electrode and the drain electrode according to a voltage applied to the gate electrode. The first transistor T1 may include a gate electrode connected to a first node N1, a source electrode connected to the drain electrode of a sixth transistor T6, and a drain electrode connected to a second node N2.

A second transistor T2 may be located or provided between one electrode of the first capacitor CP1 and the data line DL. The second transistor T2 may be turned on by the write scan signal of the write scan line GWL to connect the one electrode of the first capacitor CP1 to the data line DL. Accordingly, the data voltage of the data line DL may be applied to the one electrode of the first capacitor CP1. The second transistor T2 may include a gate electrode connected to the write scan line GWL, a source electrode connected to the data line DL, and a drain electrode connected to the one electrode of the first capacitor CP1.

A third transistor T3 may be located or provided between a first node N1 and a second node N2. The third transistor T3 may be turned on by the write control signal of the write control line GCL to connect the first node N1 to the second node N2. For this reason, if (e.g., when) the gate electrode and the source electrode of the first transistor T1 are connected, the first transistor T1 may operate like (or similar to) a diode. The third transistor T3 may include a gate electrode connected to the write control line GCL, a source electrode connected to the second node N2, and a drain electrode connected to the first node N1.

The fourth transistor T4 may be connected between the second node N2 and a third node N3. The fourth transistor T4 may be turned on by the first emission control signal of the first emission control line EL1 to connect the second node N2 to the third node N3. Accordingly, the driving current of the first transistor T1 may be supplied to the light emitting element LE. The fourth transistor T4 may include a gate electrode connected to the first emission control line EL1, a source electrode connected to the second node N2, and a drain electrode connected to the third node N3.

A fifth transistor T5 may be located or provided between the third node N3 and the third driving voltage line VIL. The fifth transistor T5 may be turned on by the bias scan signal of the bias scan line GBL to connect the third node N3 to the third driving voltage line VIL. Accordingly, the third driving voltage VINT of the third driving voltage line VIL may be applied to the first electrode of the light emitting element LE. The fifth transistor T5 may include a gate electrode connected to the bias scan line GBL, a source electrode connected to the third node N3, and a drain electrode connected to the third driving voltage line VIL.

The sixth transistor T6 may be located or provided between the source electrode of the first transistor T1 and the second driving voltage line VDL. The sixth transistor T6 may be turned on by the second emission control signal of the second emission control line EL2 to connect the source electrode of the first transistor T1 to the second driving voltage line VDL. Accordingly, the second driving voltage VDD of the second driving voltage line VDL may be applied to the source electrode of the first transistor T1. The sixth transistor T6 may include a gate electrode connected to the second emission control line EL2, a source electrode connected to the second driving voltage line VDL, and a drain electrode connected to the source electrode of the first transistor T1.

The first capacitor CP1 may be formed or provided between the first node N1 and the drain electrode of the second transistor T2. The first capacitor CP1 may include one electrode connected to the drain electrode of the second transistor T2 and the other electrode connected to the first node N1.

The second capacitor CP2 may be formed or provided between the gate electrode of the first transistor T1 and the second driving voltage line VDL. The second capacitor CP2 may include one electrode connected to the gate electrode of the first transistor T1 and the other electrode connected to the second driving voltage line VDL.

The first node N1 may be a junction between the gate electrode of the first transistor T1, the drain electrode of the third transistor T3, the other electrode of the first capacitor CP1, and the one electrode of the second capacitor CP2. The second node N2 may be a junction between the drain electrode of the first transistor T1, the source electrode of the third transistor T3, and the source electrode of the fourth transistor T4. The third node N3 may be a junction between the drain electrode of the fourth transistor T4, the source electrode of the fifth transistor T5, and the first electrode of the light emitting element LE.

Each of the first to sixth transistors T1 to T6 may be a metal-oxide-semiconductor field effect transistor (MOSFET). For example, each of the first to sixth transistors T1 to T6 may be a positive type or kind (P-type or kind) MOSFET, but embodiments of the present disclosure are not limited thereto. Each of the first to sixth transistors T1 to T6 may be a negative type or kind (N-type or kind) MOSFET. In one or more embodiments, one or more of the first to sixth transistors T1 to T6 may be P-type or kind MOSFETs, and each of the remaining transistors may be an N-type or kind MOSFET.

Although it is illustrated in FIG. 3 that the first sub-pixel area SP1 includes six transistors T1 to T6 and two capacitors C1 and C2, it should be noted that the equivalent circuit diagram of the first sub-pixel area SP1 is not limited to that as illustrated in FIG. 3. For example, the number of transistors and the number of capacitors of the first sub-pixel area SP1 are not limited to those as illustrated in FIG. 3.

Further, the equivalent circuit diagram of the second sub-pixel area SP2 and the equivalent circuit diagram of the third sub-pixel area SP3 may be substantially the same as the equivalent circuit diagram of the first sub-pixel area SP1 as described in conjunction with FIG. 3. Therefore, the description of the equivalent circuit diagram of the second sub-pixel area SP2 and the equivalent circuit diagram of the third sub-pixel area SP3 may not be repeated in the present disclosure.

FIG. 4 is a layout diagram illustrating an example of a display panel according to one or more embodiments.

Referring to FIG. 4, the display area DAA of the display panel 100 according to one or more embodiments may include the plurality of pixels PX arranged or provided in a matrix form. The non-display area NDA of the display panel 100 according to one or more embodiments may include the scan driver 610, the emission driver 620, the data driver 700, a first distribution circuit 710, a second distribution circuit 720, the first pad portion PDA1, and a second pad portion PDA2.

The scan driver 610 may be located or provided on the first side of the display area DAA, and the emission driver 620 may be located or provided on the second side of the display area DAA. For example, the scan driver 610 may be located or provided on one side of the display area DAA in the first direction DR1, and the emission driver 620 may be located or provided on the other side of the display area DAA in the first direction DR1. In one or more embodiments, the scan driver 610 may be located or provided on the left side of the display area DAA, and the emission driver 620 may be located or provided on the right side of the display area DAA. However, embodiments of the present disclosure are not limited thereto, and the scan driver 610 and the emission driver 620 may be located or provided on both (e.g., simultaneously) the first side and the second side of the display area DAA.

The first pad portion PDA1 may include the plurality of first pads PD1 connected to pads or bumps of the circuit board 300 through a conductive (e.g., electrically conductive) adhesive member. The first pad portion PDA1 may be located or provided on the third side of the display area DAA. For example, the first pad portion PDA1 may be located or provided on one side of the display area DAA in the second direction DR2. The first pad portion PDA1 may be located or provided outside the data driver 700 in the second direction DR2. In one or more embodiments, the first pad portion PDA1 may be located or provided closer to the edge of the display panel 100 than the data driver 700.

The second pad portion PDA2 may include a plurality of second pads PD2 corresponding to inspection pads that test whether the display panel 100 operates normally or as desired. The plurality of second pads PD2 may be connected to a jig or a probe pin during an inspection process or may be connected to a circuit board for inspection. The circuit board for inspection may be a printed circuit board including a rigid material or a flexible printed circuit board including a flexible material.

The second pad portion PDA2 may be located or provided on the fourth side of the display area DAA. For example, the second pad portion PDA2 may be located or provided on the other side of the display area DAA in the second direction DR2. The second pad portion PDA2 may be located or provided outside the second distribution circuit 720 in the second direction DR2. In one or more embodiments, the second pad portion PDA2 may be located or provided closer to the edge of the display panel 100 than the second distribution circuit 720.

The first distribution circuit 710 may distribute data voltages applied through the first pad portion PDA1 to the plurality of data lines DL. For example, the first distribution circuit 710 may distribute the data voltages applied through one first pad PD1 of the first pad portion PDA1 to the P (P is a positive integer of 2 or more) data lines DL, and as a result, the number of the plurality of first pads PD1 may be reduced. The first distribution circuit 710 may be located or provided on the third side of the display area DAA of the display panel 100. For example, the first distribution circuit 710 may be located or provided on one side of the display area DAA in the second direction DR2. In one or more embodiments, the first distribution circuit 710 may be located or provided on the lower side of the display area DAA.

The second distribution circuit 720 may distribute signals applied through the second pad portion PDA2 to the scan driver 610, the emission driver 620, and the data lines DL. The second pad portion PDA2 and the second distribution circuit 720 may be configured or provided to inspect the operation of each of the pixels PX in the display area DAA. The second distribution circuit 720 may be located or provided on the fourth side of the display area DAA of the display panel 100. For example, the second distribution circuit 720 may be located or provided on the other side of the display area DAA in the second direction DR2. In one or more embodiments, the second distribution circuit 720 may be located or provided on the upper side of the display area DAA.

The display device 10 may include an active area that implements an image and a non-active area that is located or provided outside the active area and does not implement an image (e.g., the image and/or an other image). Herein, the maximum width of the active area may be, for example, about 1.5 inches or less. Herein, the maximum width may refer to the longest lateral length that may be measured in the active area. For example, if (e.g., when) the display device 10 has a quadrilateral shape (e.g., a substantially quadrilateral shape), the maximum width as described in one or more embodiments may correspond to the diagonal length of the display device 10.

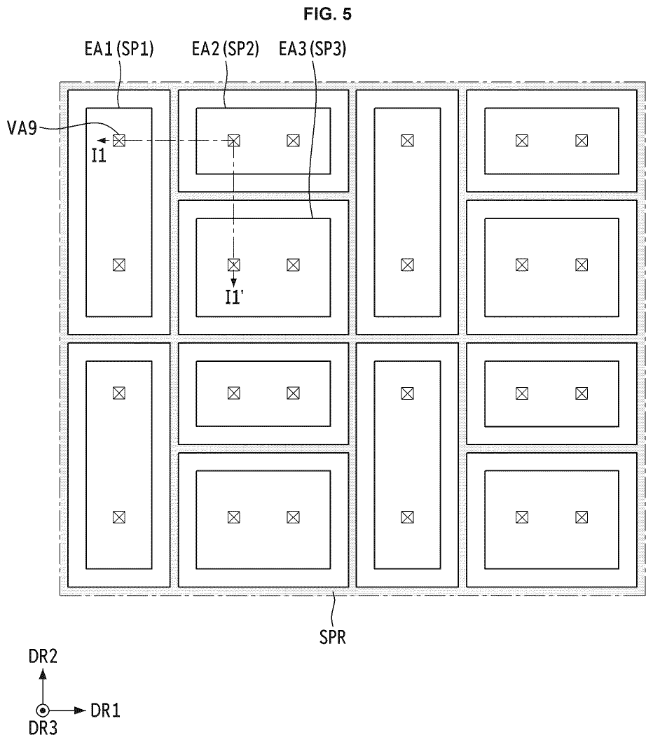

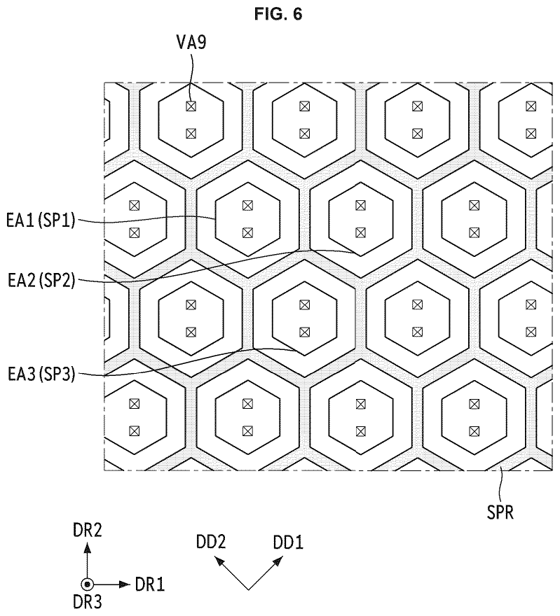

FIGS. 5 and 6 are layout diagrams illustrating examples of the display area of FIG. 4.

Referring to FIGS. 5 and 6, each of the pixels PX may include a first emission area EA1 that is an emission area of the first sub-pixel area SP1, a second emission area EA2 that is an emission area of the second sub-pixel area SP2, and a third emission area EA3 that is an emission area of the third sub-pixel area SP3.

Each of the first emission area EA1, the second emission area EA2, and the third emission area EA3 may have a polygonal shape (e.g., a substantially polygonal shape), a circular shape (e.g., a substantially circular shape), an elliptical shape (e.g., a substantially elliptical shape), or atypical shape in plan view.

The maximum length of the first emission area EA1 in the first direction DR1 may be less than the maximum length of the second emission area EA2 in the first direction DR1 and the maximum length of the third emission area EA3 in the first direction DR1. The maximum length of the second emission area EA2 in the first direction DR1 and the maximum length of the third emission area EA3 in the first direction DR1 may be substantially the same.

The maximum length of the first emission area EA1 in the second direction DR2 may be greater than the maximum length of the second emission area EA2 in the second direction DR2 and the maximum length of the third emission area EA3 in the second direction DR2. The maximum length of the second emission area EA2 in the second direction DR2 may be less than the maximum length of the third emission area EA3 in the second direction DR2. The maximum length of the first emission area EA1 in the second direction DR2 may be greater than the maximum length of the second emission area EA2 in the second direction DR2.

The first emission area EA1, the second emission area EA2, and the third emission area EA3 may have, in plan view, a hexagonal shape (e.g., a substantially hexagonal shape) including six straight lines as illustrated in FIGS. 5 and 6, but embodiments of the present disclosure are not limited thereto. The first emission area EA1, the second emission area EA2, and the third emission area EA3 may have a polygonal shape (e.g., a substantially polygonal shape) other than a hexagonal shape (e.g., a substantially hexagonal shape), a circular shape (e.g., a substantially circular shape), an elliptical shape (e.g., a substantially elliptical shape), or an atypical shape in plan view.

As illustrated in FIG. 5, in each of the plurality of pixels PX, the first emission area EA1, and the second emission area EA2 may be adjacent to each other in the first direction DR1. Further, the first emission area EA1 and the third emission area EA3 may be adjacent to each other in the first direction DR1. In one or more embodiments, the second emission area EA2 and the third emission area EA3 may be adjacent to each other in the second direction DR2. The area of the first emission area EA1, the area of the second emission area EA2, and the area of the third emission area EA3 may be different.

In one or more embodiments, as illustrated in FIG. 6, the first emission area EA1 and the second emission area EA2 may be adjacent to each other in the first direction DR1, but the second emission area EA2 and the third emission area EA3 may be adjacent to each other in a first diagonal direction DD1, and the first emission area EA1 and the third emission area EA3 may be adjacent to each other in a second diagonal direction DD2. The first diagonal direction DD1 may be a direction between the first direction DR1 and the second direction DR2 and may refer to a direction inclined by about 45 degrees with respect to the first direction DR1 and the second direction DR2, and the second diagonal direction DD2 may be a direction perpendicular (e.g., substantially perpendicular) to the first diagonal direction DD1.

The first sub-pixel area SP1 may emit first light that has passed through a first color filter CF1 (see FIG. 7) among lights emitted from the first emission area EA1, the second sub-pixel area SP2 may emit second light that has passed through a second color filter CF2 (see FIG. 7) among lights emitted from the second emission area EA2, and the third sub-pixel area SP3 may emit third light that has passed through a third color filter CF3 (see FIG. 7) among lights emitted from the third emission area EA3.

The first light, the second light, and the third light as described in one or more embodiments may be lights of different wavelength bands. For example, one selected from among the first to third lights may be light of a green wavelength band, another light may be light of a red wavelength band, and the other light may be light of a blue wavelength band. Herein, the blue wavelength band may be a wavelength band of light whose main or predominant peak wavelength is in the range of about 370 nm to about 460 nm, the green wavelength band may be a wavelength band of light whose main or predominant peak wavelength is in the range of about 480 nm to about 560 nm, and the red wavelength band may be a wavelength band of light whose main or predominant peak wavelength is in the range of about 600 nm to about 750 nm.

It is exemplified in FIGS. 5 and 6 that each of the plurality of pixels PX may include three emission areas EA1, EA2, and EA3, but embodiments of the present disclosure are not limited thereto. In one or more embodiments, each of the plurality of pixels PX may include four emission areas.

In one or more embodiments, the layout of the emission areas of the plurality of pixels PX is not limited to those as illustrated in FIGS. 5 and 6. For example, the emission areas of the plurality of pixels PX may be located or provided in a stripe structure in which the emission areas are arranged or provided in the first direction DR1 or a PENTILE® structure (e.g., an RGBG matrix, RGBG structure, or RGBG matrix structure) in which the emission areas are arranged or provided in a diamond shape (e.g., a substantially diamond shape), but embodiments of the present disclosure are not limited thereto. PENTILE® is a duly registered trademark of Samsung Display Co., Ltd.

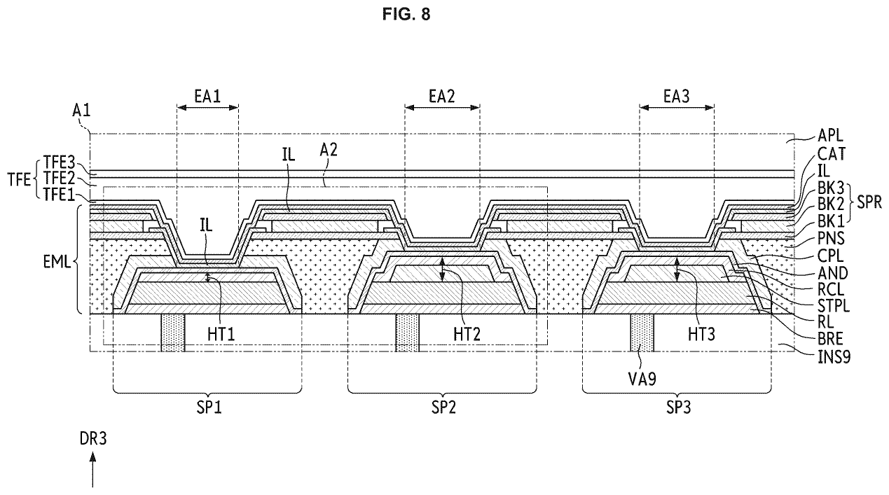

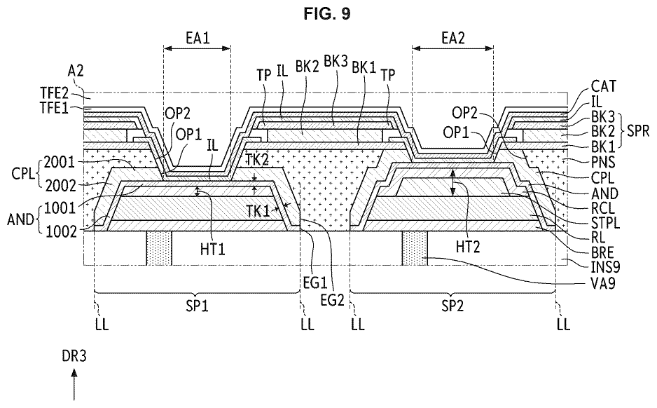

FIG. 7 is a cross-sectional view illustrating an example of a display panel taken along the line I1-I1′ of FIG. 5. FIG. 8 is a cross-sectional view illustrating the area A1 of FIG. 7 in more detail, and FIG. 9 is a cross-sectional view illustrating the area A2 of FIG. 8 in more detail.

Referring to FIGS. 7 to 9, the display panel 100 may include a semiconductor backplane SBP, a light emitting element backplane EBP, a display element layer EML, an encapsulation layer TFE, an optical layer OPL, a cover layer CVL, and a polarizing plate POL.

The semiconductor backplane SBP may include the semiconductor substrate SSUB including a plurality of pixel transistors PTR, a plurality of semiconductor insulating (e.g., electrically insulating) layers covering the plurality of pixel transistors PTR, and a plurality of contact terminals CTE electrically connected to the plurality of pixel transistors PTR, respectively. The plurality of pixel transistors PTR may be the first to sixth transistors T1 to T6 as described in one or more embodiments with reference to FIG. 3.

The semiconductor substrate SSUB may be a silicon substrate, a germanium substrate, and/or a silicon-germanium substrate. The semiconductor substrate SSUB may be a substrate doped with a first type or kind impurity. A plurality of well regions WA may be located or provided on the top surface of the semiconductor substrate SSUB. The plurality of well regions WA may be regions doped with a second type or kind impurity. The second type or kind impurity may be different from the first type or kind impurity as described in one or more embodiments. For example, if (e.g., when) the first type or kind impurity is a p-type or kind impurity, the second type or kind impurity may be an n-type or kind impurity. In one or more embodiments, if (e.g., when) the first type or kind impurity is an n-type or kind impurity, the second type or kind impurity may be a p-type or kind impurity.

Each of the plurality of well regions WA may include a source region SA corresponding to the source electrode of the pixel transistor PTR, a drain region DA corresponding to the drain electrode, and a channel region CH between the source region SA and the drain region DA.

A lower insulating layer BINS may be located or provided between a gate electrode GE and the well region WA. A side insulating layer SINS may be located or provided on the side surface of the gate electrode GE. The side insulating layer SINS may be located or provided on the lower insulating layer BINS.

Each of the source region SA and the drain region DA may be a region doped with the first type or kind impurity. The gate electrode GE of the pixel transistor PTR may overlap the well region WA in the third direction DR3, which is the thickness direction of the semiconductor substrate SSUB. The channel region CH may overlap the gate electrode GE in the third direction DR3. The source region SA may be located or provided on one side of the gate electrode GE, and the drain region DA may be located or provided on the other side of the gate electrode GE.

Each of the plurality of well regions WA may further include a first low-concentration impurity region LDD1 located or provided between the channel region CH and the source region SA and a second low-concentration impurity region LDD2 between the channel region CH and the drain region DA. The first low-concentration impurity region LDD1 may be a region having a lower impurity concentration than the source region SA due to the lower insulating layer BINS. The second low-concentration impurity region LDD2 may be a region having a lower impurity concentration than the drain region DA due to the lower insulating layer BINS. The distance between the source region SA and the drain region DA may increase due to the presence of the first low-concentration impurity region LDD1 and the second low-concentration impurity region LDD2. Therefore, the length of the channel region CH of each of the pixel transistors PTR may increase, so that (e.g., such that) punch-through and hot carrier phenomena that may be caused by a short channel may be reduced or prevented.

A first semiconductor insulating layer SINS1 may be located or provided on the semiconductor substrate SSUB. The first semiconductor insulating layer SINS1 may be formed or provided as a silicon carbonitride (SiCN)-based inorganic film and/or a silicon oxide (e.g., SiOₓ, wherein 0<x≤2; e.g., SiO₂)-based inorganic film, but embodiments of the present disclosure are not limited thereto.

A second semiconductor insulating layer SINS2 may be located or provided on the first semiconductor insulating layer SINS1. The second semiconductor insulating layer SINS2 may be formed or provided as a silicon oxide (e.g., SiOₓ, wherein 0<x≤2; e.g., SiO₂)-based inorganic film, but embodiments of the present disclosure are not limited thereto.

The plurality of contact terminals CTE may be located or provided on the second semiconductor insulating layer SINS2. Each of the plurality of contact terminals CTE may be connected to any one selected from among the gate electrode GE, the source region SA, and the drain region DA of each of the pixel transistors PTR through holes penetrating the first semiconductor insulating layer SINS1 and the second semiconductor insulating layer INS2. The plurality of contact terminals CTE may include any one selected from among copper (Cu), aluminum (Al), tungsten (W), molybdenum (Mo), chromium (Cr), gold (Au), titanium (Ti), nickel (Ni), and neodymium (Nd), or an alloy including any one selected from among them.

A third semiconductor insulating layer SINS3 may be located or provided on a side surface of each of the plurality of contact terminals CTE. The top surface of each of the plurality of contact terminals CTE may be exposed without being covered by the third semiconductor insulating layer SINS3. The third semiconductor insulating layer SINS3 may be formed or provided as a silicon oxide (e.g., SiOₓ, wherein 0<x≤2; e.g., SiO₂)-based inorganic film, but embodiments of the present disclosure are not limited thereto.

The semiconductor substrate SSUB may be replaced with a glass substrate and/or a polymer resin substrate, such as polyimide. In this case, thin film transistors may be located or provided on the glass substrate and/or the polymer resin substrate. The glass substrate may be a rigid substrate that does not bend, and the polymer resin substrate may be a flexible substrate that may be bent and/or curved.

The light emitting element backplane EBP may include a plurality of conductive layers ML1 to ML8, a plurality of via electrodes VA1 to VA9, and a plurality of insulating layers INS1 to INS11. In one or more embodiments, the light emitting element backplane EBP may include a plurality of insulating layers INS1 to INS11 between the first to eighth conductive layers ML1 to ML8.

The first to eighth conductive layers ML1 to ML8 may serve to connect the plurality of contact terminals CTE exposed from the semiconductor backplane SBP to thereby implement the circuit of the first sub-pixel area SP1 as illustrated in FIG. 3. For example, the first to sixth transistors T1 to T6 may be formed or provided in the semiconductor backplane SBP, and the connection of the first to sixth transistors T1 to T6 and the first and second capacitors C1 and C2 may be accomplished through the first to eighth conductive layers ML1 to ML8. In one or more embodiments, the connection between or among the drain region corresponding to the drain electrode of the fourth transistor T4, the source region corresponding to the source electrode of the fifth transistor T5, and a first electrode AND of the light emitting element LE may also be accomplished through the first to eighth conductive layers ML1 to ML8.

A first insulating layer INS1 may be located or provided on the semiconductor backplane SBP. Each of first via electrodes VA1 may penetrate the first insulating layer INS1 to be connected to the contact terminal CTE exposed from the semiconductor backplane SBP. Each of first conductive layers ML1 may be located or provided on the first insulating layer INS1 and may be connected to the first via electrode VA1.

A second insulating layer INS2 may be located or provided on the first insulating layer INS1 and the first conductive layers ML1. Each of second via electrodes VA2 may penetrate the second insulating layer INS2 and be connected to the exposed first conductive layer ML1. Each of second conductive layers ML2 may be located or provided on the second insulating layer INS2 and may be connected to the second via electrode VA2.

A third insulating layer INS3 may be located or provided on the second insulating layer INS2 and the second conductive layers ML2. Each of third via electrodes VA3 may penetrate the third insulating layer INS3 and be connected to the exposed second conductive layer ML2. Each of third conductive layers ML3 may be located or provided on the third insulating layer INS3 and may be connected to the third via electrode VA3.

A fourth insulating layer INS4 may be located or provided on the third insulating layer INS3 and the third conductive layers ML3. Each of fourth via electrodes VA4 may penetrate the fourth insulating layer INS4 and be connected to the exposed third conductive layer ML3. Each of fourth conductive layers ML4 may be located or provided on the fourth insulating layer INS4 and may be connected to the fourth via electrode VA4.

A fifth insulating layer INS5 may be located or provided on the fourth insulating layer INS4 and the fourth conductive layers ML4. Each of fifth via electrodes VA5 may penetrate the fifth insulating layer INS5 and be connected to the exposed fourth conductive layer ML4. Each of fifth conductive layers ML5 may be located or provided on the fifth insulating layer INS5 and may be connected to the fifth via electrode VA5.

A sixth insulating layer INS6 may be located or provided on the fifth insulating layer INS5 and the fifth conductive layers ML5. Each of sixth via electrodes VA6 may penetrate the sixth insulating layer INS6 and be connected to the exposed fifth conductive layer ML5. Each of sixth conductive layers ML6 may be located or provided on the sixth insulating layer INS6 and may be connected to the sixth via electrode VA6.

A seventh insulating layer INS7 may be located or provided on the sixth insulating layer INS6 and the sixth conductive layers ML6. Each of seventh via electrodes VA7 may penetrate the seventh insulating layer INS7 and be connected to the exposed sixth conductive layer ML6. Each of seventh conductive layers ML7 may be located or provided on the seventh insulating layer INS7 and may be connected to the seventh via electrode VA7.

An eighth insulating layer INS8 may be located or provided on the seventh insulating layer INS7 and the seventh conductive layers ML7. Each of eighth via electrodes VA8 may penetrate the eighth insulating layer INS8 and be connected to the exposed seventh conductive layer ML7. Each of eighth conductive layers ML8 may be located or provided on the eighth insulating layer INS8 and may be connected to the eighth via electrode VA8.

The first to eighth conductive layers ML1 to ML8 and the first to eighth via electrodes VA1 to VA8 may include substantially the same material. The first to eighth conductive layers ML1 to ML8 and the first to eighth via electrodes VA1 to VA8 may include any one selected from among copper (Cu), aluminum (Al), tungsten (W), molybdenum (Mo), chromium (Cr), gold (Au), titanium (Ti), nickel (Ni), and neodymium (Nd), or an alloy including any one selected from among them. The first to eighth via electrodes VA1 to VA8 may include substantially the same material. First to eighth insulating layers INS1 to INS8 may be formed or provided as silicon oxide (e.g., SiOₓ, wherein 0<x≤2; e.g., SiO₂)-based inorganic films, but embodiments of the present disclosure are not limited thereto.

The thicknesses of the first conductive layer ML1, the second conductive layer ML2, the third conductive layer ML3, the fourth conductive layer ML4, the fifth conductive layer ML5, and the sixth conductive layer ML6 may be greater than the thicknesses of the first via electrode VA1, the second via electrode VA2, the third via electrode VA3, the fourth via electrode VA4, the fifth via electrode VA5, and the sixth via electrode VA6, respectively. The thickness of each of the second conductive layer ML2, the third conductive layer ML3, the fourth conductive layer ML4, the fifth conductive layer ML5, and the sixth conductive layer ML6 may be greater than the thickness of the first conductive layer ML1. The thickness of the second conductive layer ML2, the thickness of the third conductive layer ML3, the thickness of the fourth conductive layer ML4, the thickness of the fifth conductive layer ML5, and the thickness of the sixth conductive layer ML6 may be substantially the same. For example, the thickness of the first conductive layer ML1 may be about 1,360 Å. The thickness of each of the second conductive layer ML2, the third conductive layer ML3, the fourth conductive layer ML4, the fifth conductive layer ML5, and the sixth conductive layer ML6 may be about 1,440 Å. The thickness of each of the first via electrode VA1, the second via electrode VA2, the third via electrode VA3, the fourth via electrode VA4, the fifth via electrode VA5, and the sixth via electrode VA6 may be about 1,150 Å.

The thickness of each of the seventh conductive layer ML7 and the eighth conductive layer ML8 may be greater than the thickness of each of the first conductive layer ML1, the second conductive layer ML2, the third conductive layer ML3, the fourth conductive layer ML4, the fifth conductive layer ML5, and the sixth conductive layer ML6. The thickness of the seventh conductive layer ML7 and the thickness of the eighth conductive layer ML8 may be greater than the thickness of the seventh via electrode VA7 and the thickness of the eighth via electrode VA8, respectively. The thickness of the seventh via electrode VA7 and the thickness of the eighth via electrode VA8 may each be greater than the thickness of the first via electrode VA1, the thickness of the second via electrode VA2, the thickness of the third via electrode VA3, the thickness of the fourth via electrode VA4, the thickness of the fifth via electrode VA5, and the thickness of the sixth via electrode VA6. The thickness of the seventh conductive layer ML7 and the thickness of the eighth conductive layer ML8 may be substantially the same. For example, the thickness of each of the seventh conductive layer ML7 and the eighth conductive layer ML8 may be about 9,000 Å. The thickness of each of the seventh via electrode VA7 and the eighth via electrode VA8 may be about 6,000 Å.

A ninth insulating layer INS9 may be located or provided on the eighth insulating layer INS8 and the eighth conductive layer ML8. The ninth insulating layer INS9 may be formed or provided as a silicon oxide (e.g., SiOₓ, wherein 0<x≤2; e.g., SiO₂)-based inorganic film, but embodiments of the present disclosure are not limited thereto.

Each of ninth via electrodes VA9 may penetrate the ninth insulating layer INS9 and be connected to the exposed eighth conductive layer ML8. The ninth via electrodes VA9 may include any one selected from among copper (Cu), aluminum (Al), tungsten (W), molybdenum (Mo), chromium (Cr), gold (Au), titanium (Ti), nickel (Ni), and neodymium (Nd), or an alloy including any one selected from among them. The thickness of the ninth via electrode VA9 may be about 16,500 Å.

The display element layer EML may be located or provided on the light emitting element backplane EBP. The display element layer EML may include a plurality of barrier electrodes BRE, a plurality of reflective electrodes RL, a planarization layer PNS, a plurality of capping layers CPL, a plurality of first electrodes AND, a light emitting stack layer IL, a second electrode CAT, and a separator SPR.

Further, the display element layer EML may include the first emission area EA1, the second emission area EA2, and the third emission area EA3. Each of the first emission area EA1, the second emission area EA2, and the third emission area EA3 may be an area where the first electrode AND, the light emitting stack layer IL, and the second electrode CAT are sequentially stacked. Each of the first emission area EA1, the second emission area EA2, and the third emission area EA3 may be an area where the light emitting element LE including the first electrode AND, the light emitting stack layer IL, and the second electrode CAT is located or provided. Each of the first emission area EA1, the second emission area EA2, and the third emission area EA3 may be partitioned by the capping layer CPL.

The plurality of barrier electrodes BRE may be located or provided on the ninth insulating layer INS9. For example, the plurality of barrier electrodes BRE may be located or provided on the ninth insulating layer INS9 to be respectively connected to the plurality of ninth via electrodes VA9. The barrier electrode BRE may prevent a material (e.g., aluminum) included in the ninth reflective electrode RL from being diffused (or reduce a degree to or occurrence of which a material (e.g., aluminum) included in the ninth reflective electrode RL is diffused). The plurality of barrier electrodes BRE may include titanium nitride (e.g., TiNₓ, wherein 0<x≤2; e.g., TiN) and/or transparent (e.g., substantially transparent) conductive (e.g., electrically conductive) oxide. For example, the transparent conductive oxide may be indium tin oxide (ITO) and/or indium zinc oxide (IZO), but embodiments of the present disclosure are not limited thereto.

The plurality of reflective electrodes RL may be respectively located or provided on the plurality of barrier electrodes BRE. Each of the reflective electrodes RL may include any one selected from among copper (Cu), aluminum (Al), tungsten (W), molybdenum (Mo), chromium (Cr), gold (Au), titanium (Ti), nickel (Ni), and neodymium (Nd), or an alloy including any one selected from among them. For example, each of the reflective electrodes RL may include aluminum (Al) having high reflectivity.

A step layer STPL may be located or provided on the reflective electrode RL in each of the second sub-pixel areas SP2 and the third sub-pixel areas SP3. In one or more embodiments, the step layer STPL may not be located or provided in each of the first sub-pixel areas SP1. For example, the step layer STPL may be located or provided between the reflective electrode RL and a resonance control layer RCL in the second sub-pixel area SP2 and the third sub-pixel area SP3 among the plurality of sub-pixel areas SP1, SP2, and SP3. The step layer STPL may be a layer (e.g., a step-causing layer) that causes a stepped portion (height difference) between the sub-pixel areas (e.g., SP1 and SP2) that emit light of different colors (or different wavelength bands). The step layer STPL may be formed or provided as a silicon carbonitride (SiCN)-based inorganic film and/or a silicon oxide (e.g., SiOₓ, wherein 0<x≤2; e.g., SiO₂)-based inorganic film, but embodiments of the present disclosure are not limited thereto.

The resonance control layers RCL may be respectively located or provided on the reflective electrodes RL and the step layers STPL. The resonance control layer RCL may be formed or provided as a silicon oxide (e.g., SiOₓ, wherein 0<x≤2; e.g., SiO₂)-based inorganic film, but embodiments of the present disclosure are not limited thereto.

In each of the first sub-pixel areas SP1, the resonance control layer RCL may be located or provided on the reflective electrode RL. For example, in each of the first sub-pixel areas SP1, the resonance control layer RCL may cover the top surface of the reflective electrode RL.

In each of the second sub-pixel areas SP2, the resonance control layer RCL may be located or provided on the reflective electrode RL and the step layer STPL. For example, in each of the second sub-pixel areas SP2, the resonance control layer RCL may cover the edge of the top surface of the reflective electrode RL, the top surface of the step layer STPL, and the side surface of the step layer STPL.

In each of the third sub-pixel areas SP3, the resonance control layer RCL may be located or provided on the reflective electrode RL and the step layer STPL. For example, in each of the third sub-pixel areas SP3, the resonance control layer RCL may cover the edge of the top surface of the reflective electrode RL, the top surface of the step layer STPL, and the side surface of the step layer STPL.

Due to the step layer STPL, a height HT1 of the resonance control layer RCL in the first emission area EA1 of the first sub-pixel area SP1, a height HT2 of the resonance control layer RCL in the second emission area EA2 of the second sub-pixel area SP2, and a height HT3 of the resonance control layer RCL in the third emission area EA3 of the third sub-pixel area SP3 may be different. For example, the height HT1 of the resonance control layer RCL in the first emission area EA1 may be the smallest. The height HT2 of the resonance control layer RCL in the second emission area EA2 may be greater than the height HT1 of the resonance control layer RCL in the first emission area EA1. In one or more embodiments, the height HT3 of the resonance control layer RCL in the third emission area EA3 may be substantially the same as the height HT2 of the resonance control layer RCL in the second emission area EA2. In this way, the height of the resonance control layer RCL in the first emission area EA1, the second emission area EA2, and the third emission area EA3 may vary depending on the thickness of the step layer and the number of the step layers. The height of the resonance control layer RCL may be set or predetermined in consideration of the main or predominant peak wavelength of the first light, the main or predominant peak wavelength of the second light, the main or predominant peak wavelength of the third light, the distance from the first stack layer of the light emitting stack layer to the reflective electrode RL in the first emission area EA1, the distance from the second stack layer of the light emitting stack layer to the reflective electrode RL in the second emission area EA2, and/or the distance from the third stack layer of the light emitting stack layer to the reflective electrode RL in the third emission area EA3, so that (e.g., such that) the resonance distance of the first light, the resonance distance of the second light, and the resonance distance of the third light may be set or predetermined. Herein, the height of the resonance control layer RCL in each of the emission areas EA1, EA2, and EA3 may be defined as the distance from the top surface of the reflective electrode RL to the top surface of the resonance control layer RCL in the corresponding emission area. For example, the height HT1 of the resonance control layer RCL in the first emission area EA1 as described in one or more embodiments may be defined as the distance (e.g., the distance in the third direction DR3) between the top surface (e.g., the interface between the reflective electrode RL and the resonance control layer RCL) of the reflective electrode RL and the top surface (e.g., the interface between the resonance control layer RCL and the first electrode AND) of the resonance control layer RCL in the first emission area EA1, the height HT2 of the resonance control layer RCL in the second emission area EA2 as described in one or more embodiments may be defined as the distance (e.g., the distance in the third direction DR3) between the top surface (e.g., the interface between the reflective electrode RL and the step layer STPL) of the reflective electrode RL and the top surface (e.g., the interface between the resonance control layer RCL and the first electrode AND) of the resonance control layer RCL in the second emission area EA2, and the height HT3 of the resonance control layer RCL in the third emission area EA3 as described in one or more embodiments may be defined as the distance (e.g., the distance in the third direction DR3) between the top surface (e.g., the interface between the reflective electrode RL and the step layer STPL) of the reflective electrode RL and the top surface (e.g., the interface between the resonance control layer RCL and the first electrode AND) of the resonance control layer RCL in the third emission area EA3. Because the step layer is not in the first emission area, the height HT1 of the resonance control layer RCL in the first emission area EA1 as described in one or more embodiments may be substantially the same as the thickness of the resonance control layer RCL in the first emission area EA1.

The resonance control layer RCL may be located or provided between the reflective electrode RL and a first electrode AND1 (e.g., an upper electrode portion 1001).

Each of the light emitting elements LE may include the first electrode AND, the light emitting stack layer IL, and the second electrode CAT.

The first electrode AND of each of the light emitting elements LE may be located or provided on the side surface of the barrier electrode BRE, the side surface of the reflective electrode RL, the top surface of the resonance control layer RCL, and the side surface of the resonance control layer RCL. The first electrode AND of each of the light emitting elements LE may be in contact with and electrically connected to the side surface of the reflective electrode RL and the side surface of the barrier electrode BRE.

The first electrode AND may include the upper electrode portion 1001 located or provided on the top surface of the resonance control layer RCL to overlap the top surface of the reflective electrode RL and a side electrode portion 1002 extending from the upper electrode portion 1001 to the semiconductor substrate SSUB.

The side electrode portion 1002 of the first electrode AND may be located or provided on the side surface of the resonance control layer RCL, the side surface of the reflective electrode RL, and the side surface of the barrier electrode BRE. The side surface of the resonance control layer RCL may be a surface that connects the top surface and the bottom surface of the resonance control layer RCL that are opposite to (e.g., face) each other in the third direction DR3. Between the top surface and the bottom surface of the resonance control layer RCL, the top surface may be more distant from the semiconductor substrate SSUB, and between the top surface and the bottom surface of the resonance control layer RCL, the bottom surface may be closer to the semiconductor substrate SSUB. Further, the side surface of the reflective electrode RL may be a surface that connects the top surface and the bottom surface of the reflective electrode RL that are opposite to (e.g., face) each other in the third direction DR3. Between the top surface and the bottom surface of the reflective electrode RL, the top surface may be more distant from the semiconductor substrate SSUB, and between the top surface and the bottom surface of the reflective electrode RL, the bottom surface may be closer to the semiconductor substrate SSUB. Further, the side surface of the barrier electrode BRE may be a surface that connects the top surface and the bottom surface of the barrier electrode BRE that are opposite to (e.g., face) each other in the third direction DR3. Between the top surface and the bottom surface of the barrier electrode BRE, the top surface may be more distant from the semiconductor substrate SSUB, and between the top surface and the bottom surface of the barrier electrode BRE, the bottom surface may be closer to the semiconductor substrate SSUB.

A thickness TK1 of the first electrode AND on the side surface of the resonance control layer RCL, the side surface of the reflective electrode RL, and the side surface of the barrier electrode BRE may be different from a thickness TK2 of the first electrode AND on the top surface of the resonance control layer RCL. For example, the thickness TK1 of the first electrode AND on the side surface of the resonance control layer RCL, the side surface of the reflective electrode RL, and the side surface of the barrier electrode BRE may be less than the thickness TK2 of the first electrode AND on the top surface of the resonance control layer RCL. For example, as illustrated in FIG. 9, the thickness TK1 of the side electrode portion 1002 of the first electrode AND may be less than the thickness TK2 of the upper electrode portion 1001 of the first electrode AND. According to one or more embodiments, the thickness TK1 of the side electrode portion 1002 may be about 65 Å, and the thickness TK2 of the upper electrode portion 1001 may be about 110 Å.

The first electrode AND of each of the light emitting elements LE may be connected to the drain region DA or the source region SA of the pixel transistor PTR through the barrier electrode BRE, the first to ninth via electrodes VA1 to VA9, the first to eighth conductive layers ML1 to ML8, and the contact terminal CTE.

The first electrodes AND of the sub-pixel areas SP1, SP2, and SP3 may be disconnected without being connected to each other. For example, the side electrode portion 1002 of the first electrode AND in the first sub-pixel area SP1 may be disconnected from the side electrode portion 1002 of the first electrode AND in the second sub-pixel area SP2, and the side electrode portion 1002 of the first electrode AND in the second sub-pixel area SP2 may be disconnected from the side electrode portion 1002 of the first electrode AND in the third sub-pixel area SP3. For example, if (e.g., when) a structure including the plurality of first electrodes AND in the plurality of sub-pixel areas SP1, SP2, and SP3 is defined as a single first electrode structure, the first electrode structure may be disconnected between adjacent sub-pixel areas SP1, SP2, and SP3. The first electrode AND of each of the light emitting elements LE may include any one selected from among copper (Cu), aluminum (Al), tungsten (W), molybdenum (Mo), chromium (Cr), gold (Au), titanium (Ti), nickel (Ni), and neodymium (Nd), or an alloy including any one selected from among them. For example, the first electrode AND of each of the light emitting elements LE may be titanium nitride (e.g., TiNₓ, wherein 0<x≤2; e.g., TiN).

The capping layer CPL may partition the first emission areas EA1, the second emission areas EA2, and the third emission areas EA3. The capping layer CPL may be located or provided on a part of the first electrode AND of each of the light emitting elements LE. The capping layer CPL may cover the edge of the first electrode AND of each of the light emitting elements LE. For example, the capping layer CPL may have a plurality of first openings OP1 respectively defining the plurality of emission areas EA1, EA2, and EA3. The first opening OP1 of the first emission area EA1 may penetrate the capping layer CPL to overlap the first electrode AND1 (e.g., the upper electrode portion 1001) of the first emission area EA1, the first opening OP1 of the second emission area EA2 may penetrate the capping layer CPL to overlap the first electrode AND1 (e.g., the upper electrode portion 1001) of the second emission area EA2, and the first opening OP1 of the third emission area EA3 may penetrate the capping layer CPL to overlap the first electrode AND1 (e.g., the upper electrode portion 1001) of the third emission area EA3. The capping layer CPL may include a material containing silicon nitride (e.g., SiNₓ, wherein 0<x≤2; e.g., Si₃N₄). In one or more embodiments, the capping layer CPL may include a material different from the material of the planarization layer PNS to be described herein, so that (e.g., such that) the planarization layer PNS may function as an etch stop film that defines the thickness (or height) of the planarization layer if (e.g., when) the planarization layer PNS is removed by chemical mechanical polishing (CMP).

The capping layer CPL may be in contact (or in direct contact) with the first electrode AND. The capping layer CPL may be located or provided on the first electrode AND. For example, the capping layer CPL may be located or provided on the top surface of the first electrode AND and the side surface of the first electrode AND. In this case, the capping layer CPL may be located or provided on the edge of the top surface of the first electrode AND. A disconnected surface EG2 of the capping layer CPL may be aligned with (or overlap) a disconnected surface EG1 of the first electrode AND. For example, in plan view, the disconnected surface EG2 of the capping layer CPL and the disconnected surface EG1 of the first electrode AND may be aligned with (or overlap) each other. Accordingly, the disconnected surface EG2 of the capping layer CPL and the disconnected surface EG1 of the first electrode AND may be located or provided along substantially the same imaginary plane LL. For example, the imaginary plane LL extending along the disconnected surface EG2 of the capping layer CPL may be aligned with (or overlap) the disconnected surface EG1 of the first electrode AND. Therefore, the disconnected surface EG2 of the capping layer CPL and the disconnected surface EG1 of the first electrode AND may be continuously connected to each other.

The capping layer CPL may include an upper capping portion 2001 located or provided on the upper electrode portion 1001 of the first electrode AND and a side capping portion 2002 located or provided on the side electrode portion 1002 of the first electrode AND.

The capping layers CPL of the sub-pixel areas SP1, SP2, and SP3 may be disconnected without being connected to each other. For example, the side capping portion 2002 of the capping layer CPL in the first sub-pixel area SP1 may be disconnected from the side capping portion 2002 of the capping layer CPL in the second sub-pixel area SP2, and the side capping portion 2002 of the capping layer CPL in the second sub-pixel area SP2 may be disconnected from the side capping portion 2002 of the capping layer CPL in the third sub-pixel area SP3. For example, if (e.g., when) a structure including the plurality of capping layers CPL in the plurality of sub-pixel areas SP1, SP2, and SP3 is defined as a single capping structure, the capping structure may be disconnected between adjacent sub-pixel areas SP1, SP2, and SP3.

The disconnected surface EG1 of the side electrode portion 1002 included in the first electrode AND and the disconnected surface EG2 of the side capping portion 2002 included in the capping layer CPL may be in one plane LL (e.g., substantially the same imaginary plane LL).

The disconnected surface EG1 of the side electrode portion 1002 included in the first electrode AND and the disconnected surface EG2 of the side capping portion 2002 included in the capping layer CPL may be in contact (or direct contact) with the planarization layer PNS.

The first emission area EA1 may be defined as an area in which the first electrode AND, the light emitting stack layer IL, and the second electrode CAT are sequentially stacked in the first sub-pixel area SP1 to emit light. The second emission area EA2 may be defined as an area in which the first electrode AND, the light emitting stack layer IL, and the second electrode CAT are sequentially stacked in the second sub-pixel area SP2 to emit light. The third emission area EA3 may be defined as an area in which the first electrode AND, the light emitting stack layer IL, and the second electrode CAT are sequentially stacked in the third sub-pixel area SP3 to emit light.

The planarization layer PNS may be a planarization layer capable of planarizing the stepped portion between the sub-pixel areas SP1, SP2, and SP3 caused by the step layer STPL. The planarization layer PNS may be located or provided on the capping layer CPL. For example, the planarization layer PNS may be located or provided on the top surface and the side surface of the capping layer CPL. In this case, the planarization layer PNS may be in contact (or in direct contact) with the capping layer CPL and may be in contact (or in direct contact) with the first electrode AND. For example, the planarization layer PNS may be in contact (or direct contact) with each of the side surface of the capping layer CPL including the disconnected surface EG2 of the capping layer CPL, the top surface of the capping layer CPL, and the disconnected surface EG1 of the first electrode AND.

Further, the planarization layer PNS may include a second opening OP2 penetrating the planarization layer PNS in the third direction DR3. The second opening OP2 of the planarization layer PNS may overlap the first opening OP1 of the capping layer CPL. For example, the plurality of second openings OP2 of the planarization layer PNS may respectively overlap the emission areas EA1, EA2, and EA3 of the capping layer CPL.

Further, the interface between the planarization layer PNS and the capping layer CPL and the interface between the planarization layer PNS and the first electrode AND may be in the imaginary plane LL as described in one or more embodiments. For example, the interface between the disconnected surface EG2 of the capping layer CPL and the planarization layer PNS and the interface between the disconnected surface EG1 of the first electrode AND and the planarization layer PNS may be aligned with (or overlap) each other to be located or provided along the imaginary plane LL as described in one or more embodiments. Therefore, the interface between the disconnected surface EG2 of the capping layer CPL and the planarization layer PNS and the interface between the disconnected surface EG1 of the first electrode AND and the planarization layer PNS may be continuously connected to each other. The planarization layer PNS may include a material containing silicon oxide (e.g., SiOₓ, wherein 0<x≤2; e.g., SiO₂).

The separator SPR may be located or provided on the capping layers CPL and the planarization layer. In plan view, as illustrated in FIGS. 5 and 6, the separator SPR may have a mesh shape (e.g., a substantially mesh shape) around (e.g., surrounding) each of the emission areas EA1, EA2, and EA3. The separator SPR may be located or provided on the capping layer CPL and the planarization layer PNS to be around (e.g., surround) each of the emission areas EA1, EA2, and EA3. However, embodiments of the present disclosure are not limited thereto, and a plurality of separators may be around (e.g., surround) the plurality of emission areas EA1, EA2, and EA3, respectively. In this case, each separator may have a closed curve shape (e.g., a substantially closed curve shape). The separator SPR may be a structure to cut the light emitting stack layer IL. To this end, according to one or more embodiments, the separator SPR may include a first bank BK1, a second bank BK2, and a third bank BK3 having different areas.

The first bank BK1 may be located or provided on the planarization layer PNS and the capping layer CPL. The first bank BK1 may include substantially the same material as the planarization layer PNS. For example, the first bank BK1 may include a material containing silicon oxide (e.g., SiOₓ, wherein 0<x≤2; e.g., SiO₂). In this case, the first bank BK1 and the planarization layer PNS may be formed or provided integrally without an interface.

The second bank BK2 may be located or provided on the first bank BK1. The second bank BK2 may be located or provided on the second bank BK2 to overlap the first bank BK1. In this case, the area of the second bank BK2 may be less than the area of the first bank BK1. For example, in plan view, the area of the second bank BK2 may be less than the area of the first bank BK1 so that (e.g., such that) the second bank BK2 may be surrounded by the edge of the first bank BK1. The etching rate of the second bank BK2 may be different from the etching rate of the first bank BK1. For example, the etching rate of the second bank BK2 may be greater than the etching rate of the first bank BK1. The second bank BK2 may include a material containing silicon nitride (e.g., SiNₓ, wherein 0<x≤2; e.g., Si₃N₄). In one or more embodiments, the second bank BK2 may include a material containing metal. For example, the second bank may include a material including at least one of titanium (Ti), tantalum (Ta), or molybdenum (Mo).

The third bank BK3 may be located or provided on the second bank BK2. The third bank BK3 may be located or provided on the second bank BK2 to overlap the second bank BK2. In this case, the area of the third bank BK3 may be greater than the area of the first bank BK1. For example, in plan view, the area of the third bank BK3 may be greater than the area of the second bank BK1 so that (e.g., such that) the third bank BK3 may be around (e.g., surround) the edge of the second bank BK2. Accordingly, as illustrated in FIG. 9, the third bank BK3 may include a tip TP that does not overlap the second bank BK2. The etching rate of the second bank BK2 may be different from the etching rate of the third bank BK3. For example, the etching rate of the second bank BK2 may be greater than the etching rate of the third bank BK3. The third bank BK3 may include a material containing silicon oxide (e.g., SiOₓ, wherein 0<x≤2; e.g., SiO₂).

The width of the separator SPR including the first bank BK1, the second bank BK2, and the third bank BK3 may be smaller at the center than at the upper side and the lower side in cross-sectional view. For example, in a direction parallel (e.g., substantially parallel) to the semiconductor substrate SSUB, the edge of an upper bank (e.g., the third bank BK3) may extend toward the first opening OP1 of the capping layer CPL while passing through the edge of a lower bank (e.g., the second bank BK2). Accordingly, in plan view, the edge of the lower bank BK2 may be surrounded by the edge of the upper bank BK3.

The light emitting stack layer IL may be located or provided on the first electrodes AND, the capping layers CPL, and the separators SPR. In this case, the light emitting stack layer IL may be cut on the separators SPR. For example, the light emitting stack layer IL may be cut between the first bank BK1 and the third bank BK3. In cross-sectional view, the light emitting stack layer IL may be cut along the separator SPR. Therefore, the light emitting stack layer IL may be divided into a portion in contact with the first electrode AND in the emission area and a portion located or provided on the area (e.g., the third bank BK3 of the separator SPR) except the emission area. For example, the light emitting stack layer IL may be cut along the separator SPR to be separated for each sub-pixel area. Accordingly, the lateral leakage current between adjacent sub-pixel areas SP1, SP2, and SP3 may be minimized or reduced. Because the lateral leakage current is minimized or reduced, the color mixing phenomenon between adjacent sub-pixel areas SP1, SP2, and SP3 may be prevented (or a degree or occurrence of the color mixing phenomenon between adjacent sub-pixel areas SP1, SP2, and SP3 may be reduced), thereby improving or enhancing the image quality of the display device 10.

The light emitting stack layer IL may include a plurality of stack layers that are sequentially stacked along the third direction DR3. For example, the light emitting stack layer IL may have a three-tandem structure including a first stack layer, a second stack layer on the first stack layer, and a third stack layer on the second stack layer. Herein, the second stack layer may be located or provided between the first stack layer and the third stack layer. However, embodiments of the present disclosure are not limited thereto. For example, the light emitting stack layer IL may have a two-tandem structure including two stack layers.

In the three-tandem structure, the first stack layer, the second stack layer, and the third stack layer of the light emitting stack layer IL may provide lights of different colors (or wavelengths). For example, one selected from among the first stack layer, the second stack layer, and the third stack layer may provide light of a first color (e.g., green), another stack layer may provide light of a second color (e.g., red), and the other stack layer may provide light of a third color (e.g., blue).

The first stack layer of the light emitting stack layer IL may have a structure in which a first hole transporting layer, a first organic light emitting layer, and a first electron transporting layer are sequentially stacked. The second stack layer of the light emitting stack layer IL may have a structure in which a second hole transporting layer, a second organic light emitting layer, and a second electron transporting layer are sequentially stacked. The third stack layer of the light emitting stack layer IL may have a structure in which a third hole transporting layer, a third organic light emitting layer, and a third electron transporting layer are sequentially stacked. Herein, the first organic light emitting layer, the second organic light emitting layer, and the third organic light emitting layer may provide lights of different colors (or wavelengths). For example, any one organic light emitting layer selected from among the first organic light emitting layer, the second organic light emitting layer, and the third organic light emitting layer may provide light of the first color (e.g., green), another organic light emitting layer may provide light of the second color (e.g., red), and the other organic light emitting layer may provide light of the third color (e.g., blue).

A first charge generation layer may be located or provided between the first stack layer and the second stack layer to supply charges to the second stack layer and supply electrons to the first stack layer. The first charge generation layer may include an n-type or kind charge generation layer that supplies electrons to the first stack layer and a p-type or kind charge generation layer that supplies holes to the second stack layer. The n-type or kind charge generation layer may include a dopant of a metal material.

A second charge generation layer may be located or provided between the second stack layer and the third stack layer to supply charges to the third stack layer and supply electrons to the second stack layer. The second charge generation layer may include an n-type or kind charge generation layer that supplies electrons to the second stack layer and a p-type or kind charge generation layer that supplies holes to the third stack layer.

The first stack layer may be located or provided on the first electrodes AND and the capping layer CPL. The first stack layer of the light emitting stack layer IL may be disconnected between the sub-pixel areas SP1, SP2, and SP3 adjacent to each other by the separator SPR as described in one or more embodiments. The second stack layer of the light emitting stack layer IL may be located or provided on the first stack layer. The second stack layer of the light emitting stack layer IL may be disconnected between the sub-pixel areas SP1, SP2, and SP3 adjacent to each other by the separator SPR as described in one or more embodiments. The third stack layer of the light emitting stack layer IL may be located or provided on the second stack layer. The third stack layer of the light emitting stack layer IL may not be disconnected by the separator SPR and may be located or provided to cover the second stack layer.

In the three-tandem structure, the separator SPR may be a structure to disconnect the first charge generation layer and the second charge generation layer of the display element layer EML between the sub-pixel areas SP1, SP2, and SP3 adjacent to each other. Further, in the two-tandem structure, the separator SPR may be a structure to disconnect the charge generation layer located or provided between the lower stack layer and the upper stack layer.

The second electrode CAT may be located or provided on the light emitting stack layer IL. For example, the second electrode CAT may be located or provided on the third stack layer of the light emitting stack layer IL. The second electrode CAT may be located or provided on the third stack layer of the light emitting stack layer IL without being disconnected by the separator SPR. The second electrode CAT may include a transparent (e.g., substantially transparent) conductive (e.g., electrically conductive) material (TCO) or a semi-transmissive conductive (e.g., electrically conductive) material, such as magnesium (Mg), silver (Ag), or an alloy of magnesium (Mg) and silver (Ag). In this case, light emission efficiency in each of the first to third sub-pixel areas SP1, SP2, and SP3 may be increased or enhanced due to a micro-cavity effect.

The encapsulation layer TFE may be located or provided on the display element layer EML. The encapsulation layer TFE may include at least one inorganic film TFE1 and TFE2 to reduce or prevent oxygen and/or moisture from permeating into the display element layer EML. For example, the encapsulation layer TFE may include a first encapsulation inorganic film TFE1, an encapsulation organic film TFE2, and a second encapsulation inorganic film TFE3.

The first encapsulation inorganic film TFE1 may be located or provided on the second electrode CAT. The first encapsulation inorganic film TFE1 may be formed or provided as a multilayer in which one or more inorganic films selected from among silicon nitride (e.g., SiNₓ, wherein 0<x≤2; e.g., Si₃N₄), silicon nitride oxide or silicon oxynitride (e.g., SiOₓN_{y}, wherein 0<x≤2 and 0≤y≤2; e.g., SiON or Si₂N₂O), and silicon oxide (e.g., SiOₓ, wherein 0<x≤2; e.g., SiO₂) are alternately stacked. The first encapsulation inorganic film TFE1 may be formed or provided by a chemical vapor deposition (CVD) process.

The encapsulation organic film TFE2 may be a monomer. In one or more embodiments, the encapsulation organic film TFE2 may be an organic film made of a resin, such as an acryl resin, an epoxy resin, a phenolic resin, a polyamide resin, a polyimide resin, and/or the like.

The second encapsulation inorganic film TFE3 may be located or provided on the encapsulation organic film TFE2. The second encapsulation inorganic film TFE2 may be formed or provided as a multilayer in which one or more inorganic films selected from among silicon nitride (e.g., SiNₓ, wherein 0<x≤2; e.g., Si₃N₄), silicon nitride oxide or silicon oxynitride (e.g., SiOₓN_{y}, wherein 0<x≤2 and 0≤y≤2; e.g., SiON or Si₂N₂O), and silicon oxide (e.g., SiOₓ, wherein 0<x≤2; e.g., SiO₂) are alternately stacked. The second encapsulation inorganic film TFE3 may be formed or provided by a chemical vapor deposition (CVD) process.

An organic film APL may be a layer to increase or enhance the interfacial adhesion between the encapsulation layer TFE and the optical layer OPL. The organic film APL may be an organic film made of a resin, such as an acrylic resin, an epoxy resin, a phenolic resin, a polyamide resin, and/or a polyimide resin.

The optical layer OPL may include a plurality of color filters CF1, CF2, and CF3, a plurality of lenses LNS, and a filling layer FIL. The plurality of color filters CF1, CF2, and CF3 may include the first to third color filters CF1, CF2, and CF3. The first to third color filters CF1, CF2, and CF3 may be located or provided on the adhesive layer ADL.

The first color filter CF1 may overlap the first emission area EA1 of the first sub-pixel area SP1. The first color filter CF1 may transmit the first light (e.g., light of a green wavelength band). Thus, the first color filter CF1 may transmit the first light among light emitted from the light emitting stack layer IL of the first emission area EA1.

The second color filter CF2 may overlap the second emission area EA2 of the second sub-pixel area SP2. The second color filter CF2 may transmit the second light (e.g., light of a red wavelength band). Thus, the second color filter CF2 may transmit the second light among light emitted from the light emitting stack layer IL of the second emission area EA2.

The third color filter CF3 may overlap the third emission area EA3 of the third sub-pixel area SP3. The third color filter CF3 may transmit the third light (e.g., light of a blue wavelength band). Thus, the third color filter CF3 may transmit the third light among light emitted from the light emitting stack layer IL of the third emission area EA3.

The plurality of lenses LNS may be located or provided on the first color filter CF1, the second color filter CF2, and the third color filter CF3, respectively. Each of the plurality of lenses LNS may be a structure to increase the proportion of light directed to the front of the display device 10. Although each of the lenses LNS is illustrated as having a cross-sectional shape that is convex upward, embodiments of the present disclosure are not limited thereto.

The filling layer FIL may be located or provided on the plurality of lenses LNS. The filling layer FIL may have a selected (e.g., set or predetermined) refractive index such that light travels in the third direction DR3 at an interface between the filling layer FIL and the plurality of lenses LNS. Further, the filling layer FIL may be a planarization layer. The filling layer FIL may be an organic film made of a resin, such as an acrylic resin, an epoxy resin, a phenolic resin, a polyamide resin, and/or a polyimide resin.

The cover layer CVL may be located or provided on the filling layer FIL. The cover layer CVL may be a glass substrate and/or a polymer resin. If (e.g., when) the cover layer CVL is a glass substrate, it may be attached onto the filling layer FIL. In this case, the filling layer FIL may serve to bond the cover layer CVL. If (e.g., when) the cover layer CVL is a glass substrate, it may serve as an encapsulation substrate. If (e.g., when) the cover layer CVL is a polymer resin, it may be directly applied onto the filling layer FIL.

The polarizing plate POL may be located or provided on one surface of the cover layer CVL. The polarizing plate POL may be a structure to reduce or prevent visibility degradation caused by reflection of external light. The polarizing plate POL may include a linear polarizing plate and a phase retardation film. For example, the phase retardation film may be a λ/4 plate (quarter-wave plate), but embodiments of the present disclosure are not limited thereto. However, if (e.g., when) visibility degradation caused by reflection of external light is sufficiently or suitably overcome by the first to third color filters CF1, CF2, and CF3, the polarizing plate POL may not be provided.

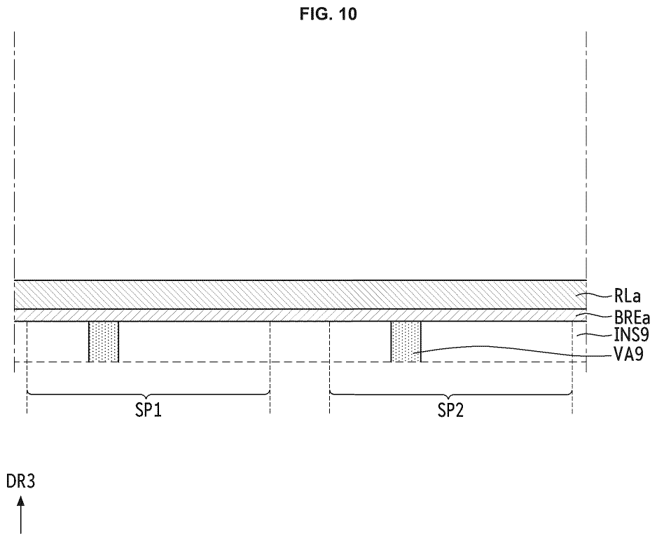

FIGS. 10, 11, 12, 13, 14, 15, 16, 17, 18, 19, 20, 21, 22, 23, 24, 25, and 26 are process views illustrating a method for fabricating a display device according to one or more embodiments. For example, FIGS. 10 to 26 may be process cross-sectional views to illustrate the method for fabricating the display device of FIG. 9.

First, as illustrated in FIG. 10, the ninth insulating layer INS9 may be formed or provided on the semiconductor substrate SSUB, and the ninth via electrode VA9 may be formed or provided in the ninth insulating layer INS9. Thereafter, a preliminary barrier electrode BREa may be formed or provided on the ninth insulating layer INS9 to be in contact with the ninth via electrode VA9. Next, a preliminary reflective electrode RLa may be formed or provided on the preliminary barrier electrode BREa.

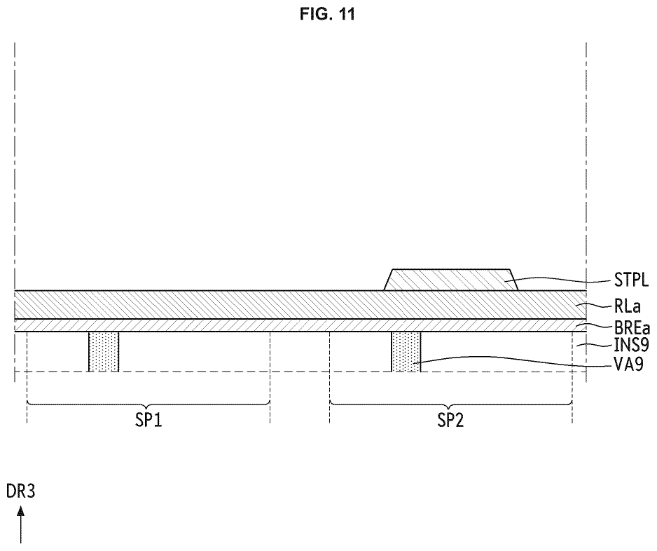

Next, as illustrated in FIG. 11, the step layer STPL may be formed or provided on the preliminary reflective electrode RLa. For example, the step layer STPL may be formed or provided on the preliminary reflective electrode RLa to correspond to the second emission area EA2 of the second sub-pixel area SP2 and the third emission area EA3 of the third sub-pixel area SP3.

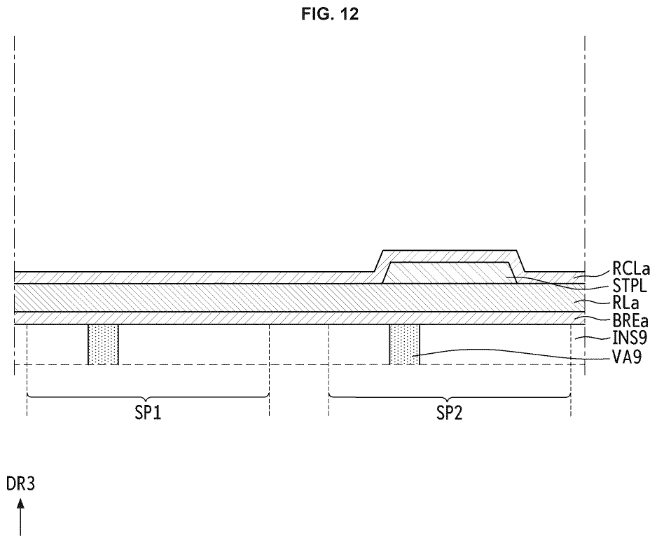

Thereafter, as illustrated in FIG. 12, a preliminary resonance control layer RCLa may be formed or provided on the preliminary reflective electrode RLa and the step layer STPL. In this case, the preliminary resonance control layer RCLa may be formed or provided on the top surface of the preliminary reflective electrode RLa, the top surface of the step layer STPL, and the side surface of the step layer STPL.

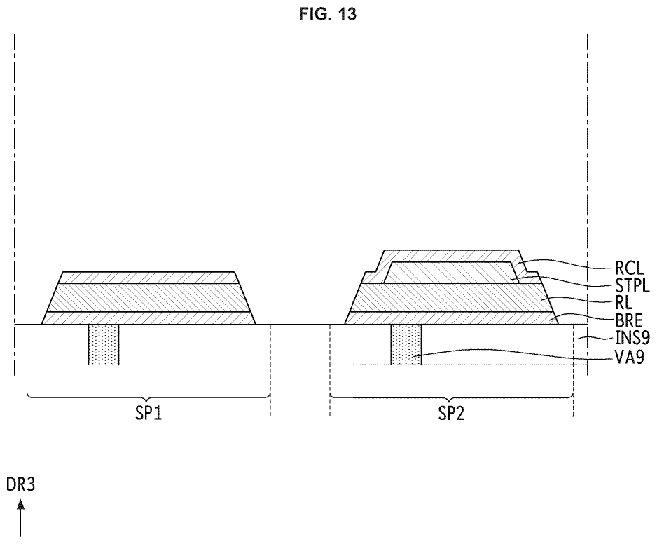

Next, the preliminary resonance control layer RCLa, the preliminary reflective electrode RLa, and the preliminary barrier electrode BREa may be patterned, so that (e.g., such that) the barrier electrode BRE, the reflective electrode RL, and the resonance control layer RCL may be formed or provided for each of the sub-pixel area SP1, SP2, and SP3, as illustrated in FIG. 13. For example, the preliminary resonance control layer RCLa, the preliminary reflective electrode RLa, and the preliminary barrier electrode BREa may be etched and patterned by an etching process, so that (e.g., such that) the barrier electrode BRE, the reflective electrode RL, and the resonance control layer RCL may be formed or provided for each of the sub-pixel areas SP1, SP2, and SP3. In this case, the ninth insulating layer INS9 may be exposed.

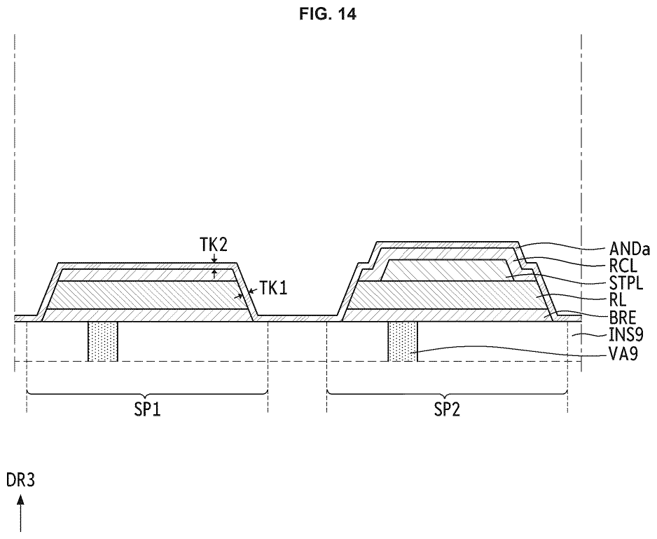

Next, as illustrated in FIG. 14, a first preliminary electrode ANDa may be formed or provided on the ninth insulating layer INS9 and the resonance control layer RCL. In this case, the first preliminary electrode ANDa may be formed or provided on the top surface of each resonance control layer RCL, the side surface of each resonance control layer RCL, the side surface of each reflective electrode RL, and the side surface of each barrier electrode BRE. Herein, the thickness TK1 of the first preliminary electrode ANDa on the side surface of the resonance control layer RCL, the side surface of the reflective electrode RL, and the side surface of the barrier electrode BRE may be less than the thickness TK2 of the first preliminary electrode ANDa on the top surface of the resonance control layer RCL.

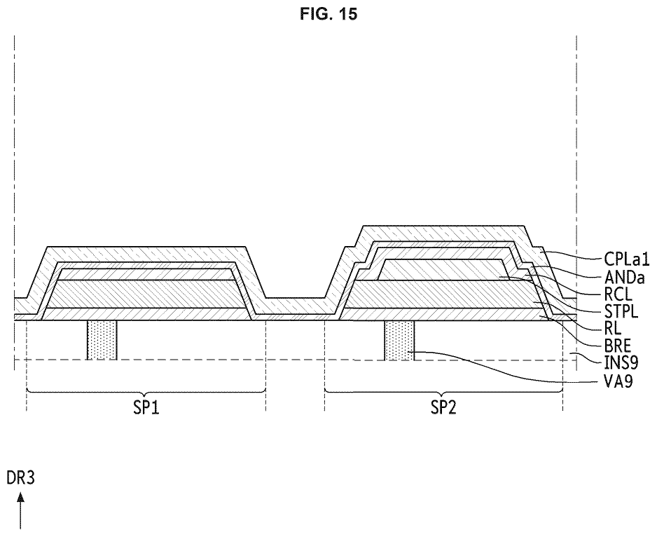

Thereafter, as illustrated in FIG. 15, a first preliminary capping layer CPLa1 may be formed or provided on the first preliminary electrode ANDa.

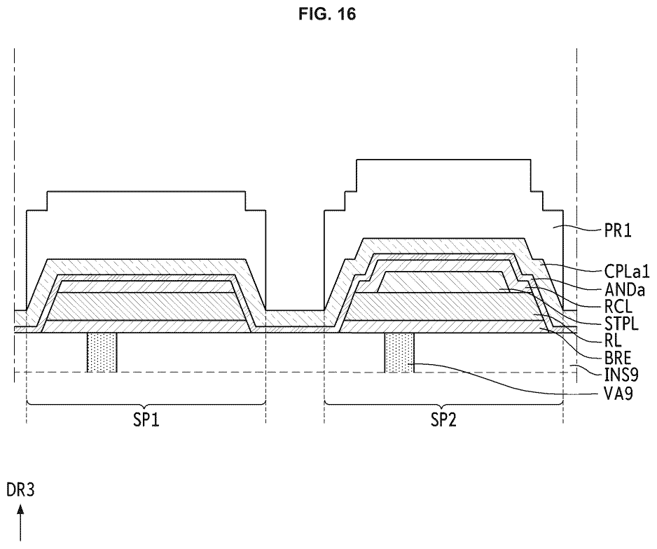

Next, as illustrated in FIG. 16, a first photoresist pattern PR1 may be formed or provided on the first preliminary capping layer CPLa1. For example, the first photoresist pattern PR1 may be formed or provided on the first preliminary capping layer CPLa1 to overlap each of the emission areas EA1, EA2, and EA3.

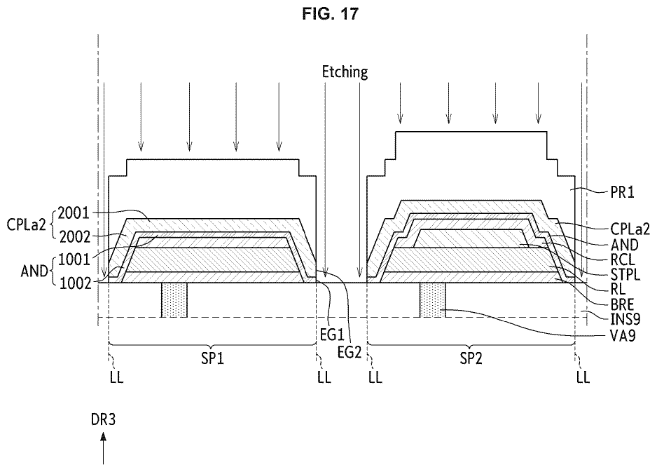

Thereafter, as illustrated in FIG. 17, the first preliminary capping layer CPLa1 and the first preliminary electrode ANDa may be patterned together utilizing the first photoresist pattern PR1 as a mask (e.g., a first mask). For example, the first preliminary capping layer CPLa1 and the first preliminary electrode ANDa may be etched and patterned together by an etching process (e.g., dry etching process) utilizing the first photoresist pattern PR1 as a mask (e.g., a first mask), so that (e.g., such that) the first electrode AND may be formed or provided for each of the sub-pixel areas SP1, SP2, and SP3, and a second preliminary capping layer CPLa2 may be formed or provided for each of the sub-pixel areas SP1, SP2, and SP3. Due to the etching process, the first electrodes AND of the sub-pixel areas SP1, SP2, and SP3 may be disconnected without being connected to each other, and the second preliminary capping layers CPLa2 of the sub-pixel areas SP1, SP2, and SP3 may disconnected without being connected to each other. The first electrode AND may include the upper electrode portion 1001 and the side electrode portion 1002, and the second preliminary capping layer CPLa2 may include the upper capping portion 2001 and the side capping portion 2002. The upper capping portion 2001 of the second preliminary capping layer CPLa2 may overlap the entire upper electrode portion 1001 of the first electrode AND. Accordingly, the disconnected surface EG2 of the second preliminary capping layer CPLa2 and the disconnected surface EG1 of the first electrode AND may be exposed. The disconnected surface EG2 of the second preliminary capping layer CPLa2 may be aligned with (or overlap) the disconnected surface EG1 of the first electrode AND. For example, the disconnected surface EG2 corresponding to the etched surface of the second preliminary capping layer CPLa2 and the disconnected surface EG1 corresponding to the etched surface of the first electrode AND may be aligned with (or overlap) each other. Accordingly, the disconnected surface EG2 of the second preliminary capping layer CPLa2 and the disconnected surface EG1 of the first electrode AND may be arranged or provided within substantially the same imaginary plane LL. For example, the imaginary plane LL extending along the etched surface (e.g., the disconnected surface EG2) of the patterned second preliminary capping layer CPLa2 may be aligned with (or overlap) the etched surface (e.g., the disconnected surface EG1) of the patterned first electrode AND. Therefore, the etched surface (e.g., the disconnected surface EG2) of the second preliminary capping layer CPLa2 and the etched surface (e.g., the disconnected surface EG1) of the first electrode AND may be continuously connected to each other. As described in one or more embodiments, the first preliminary capping layer CPLa1 and the first preliminary electrode ANDa may be patterned utilizing the first photoresist pattern PR1 as a mask (e.g., a first mask), so that (e.g., such that) the ninth insulating layer INS9 may be exposed.

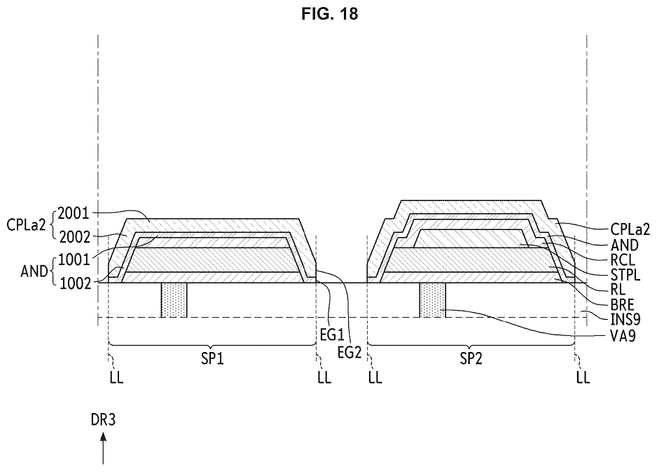

Subsequently, as illustrated in FIG. 18, the first photoresist pattern PR1 may be removed. For example, the first photoresist pattern PR1 may be removed by an ashing process. After the first photoresist pattern PR1 is removed, a cleaning process for the semiconductor substrate SSUB may be performed. For example, after the dry etching process, a polymer may remain as reaction by-products on or above the sidewall of the patterned metal, so that (e.g., such that) a cleaning process to remove the polymer utilizing a stripper including a solvent may be performed. Herein, hydrogen fluoride (e.g., diluted HF) may be used as the stripper. In this case, the side electrode portion 1002 of the first electrode AND may have a smaller thickness than another portion (e.g., the upper electrode portion 1001), so that (e.g., such that) hydrogen fluoride may permeate into the reflective electrode RL through the side electrode portion 1002 of the first electrode AND that has a relatively small thickness.

However, according to the method for fabricating a display device as described in one or more embodiments, before the cleaning process, as illustrated in FIG. 18, the second preliminary capping layer CPLa2 around (e.g., surrounding) the first electrode AND may be formed or provided on the first electrode AND, so that (e.g., such that) the permeation path of hydrogen fluoride may be blocked by the second preliminary capping layer CPLa2. For example, the upper electrode portion 1001 and the side electrode portion 1002 of the first electrode AND may be surrounded by the second preliminary capping layer CPLa2 before the cleaning process, so that (e.g., such that) the permeation of hydrogen fluoride into the reflective electrode RL through the side electrode portion 1002 having a relatively small thickness may be blocked (or a degree or occurrence of the permeation of hydrogen fluoride into the reflective electrode RL through the side electrode portion 1002 having a relatively small thickness may be reduced). Therefore, according to one or more embodiments, the reflective electrode RL including an aluminum material (e.g., a material including aluminum) may be prevented from being damaged by hydrogen fluoride (or a degree to or occurrence of which the reflective electrode RL including an aluminum material (e.g., a material including aluminum) is damaged by hydrogen fluoride may be reduced). If (e.g., when) the reflective electrode RL is exposed to hydrogen fluoride and damaged, at least a part of the reflective electrode RL may melt and be lost. In this case, the light efficiency in the emission area where the reflective electrode RL is lost may decrease, which may deteriorate the image quality of the display device.

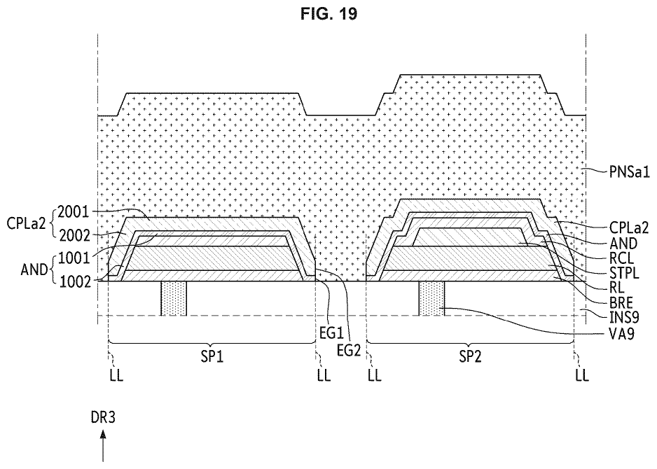

Next, as illustrated in FIG. 19, a first preliminary planarization layer PNSa1 may be formed or provided on the ninth insulating layer INS9 and the patterned second preliminary capping layer CPLa2. The first preliminary planarization layer PNSa1 may have a curvature along the stepped portion of the lower structure. In this case, the lowest portion of the first preliminary planarization layer PNSa1 may be higher than the highest portion of the second preliminary capping layer CPLa2.

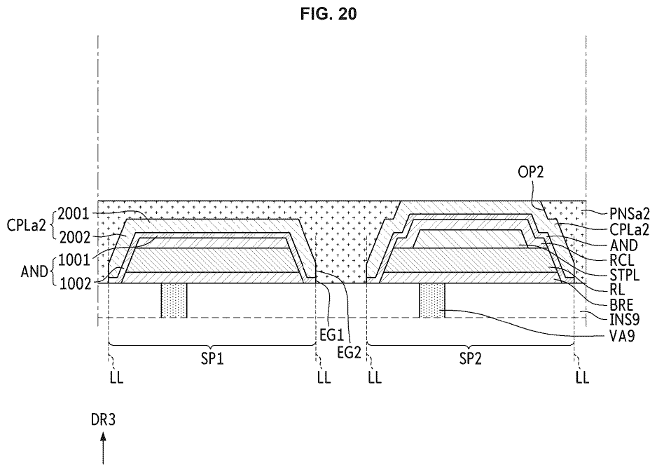

Thereafter, as illustrated in FIG. 20, the second preliminary planarization layer PNSa1 may be formed or provided by removing the first preliminary planarization layer PNSa1 located or provided above the second preliminary capping layer CPLa2. For example, a second preliminary planarization layer PNSa2 may be formed or provided by removing the first preliminary planarization layer PNSa1 by chemical mechanical polishing (CMP). For example, the first preliminary planarization layer PNSa1 may be removed until the second preliminary capping layer CPLa2 (e.g., the second preliminary capping layer CPLa2 on the first electrode AND of the second sub-pixel area SP2) at the highest portion is exposed. The top surface of the second preliminary planarization layer PNSa2 may be located or provided at substantially the same height as the highest portion of the second preliminary capping layer CPLa2. Accordingly, the second preliminary planarization layer PNSa2 may have the second opening OP2 that exposes the second preliminary capping layer CPLa2 (e.g., the upper capping portion 2001) of the second sub-pixel area SP2.

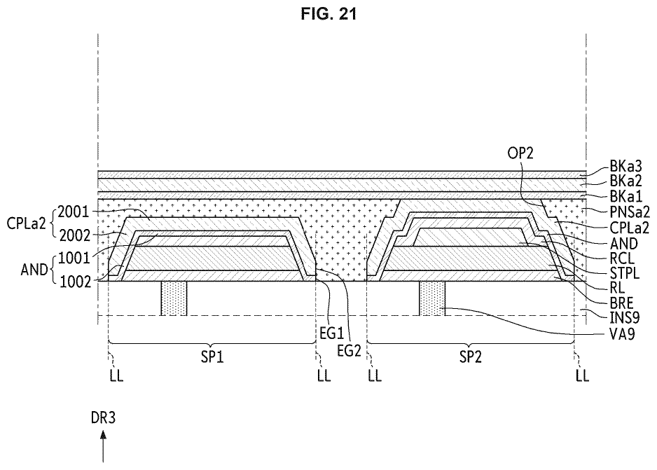

Next, as illustrated in FIG. 21, a first preliminary bank BKa1 may be formed or provided on the second preliminary planarization layer PNSa2 and the exposed second preliminary capping layer CPLa2, a second preliminary bank BKa2 may be formed or provided on the first preliminary bank BKa1, and a third preliminary bank BKa3 may be formed or provided on the second preliminary bank BKa2.

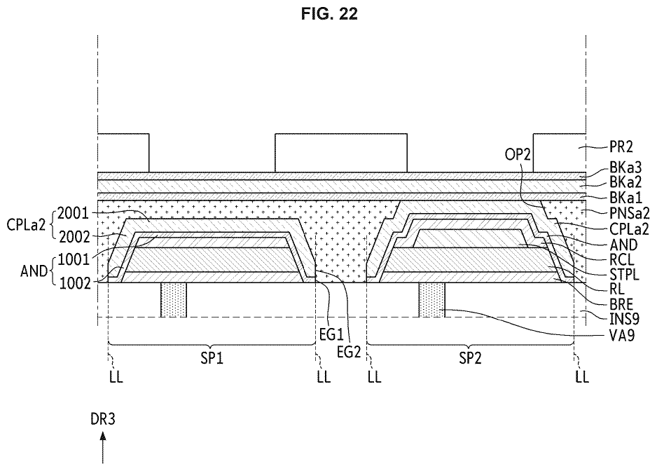

Next, as illustrated in FIG. 22, a second photoresist pattern PR2 may be formed or provided on the third preliminary bank BKa3. For example, the second photoresist pattern PR2 may be formed or provided on the third preliminary bank BKa3 so as not to overlap each of the emission areas EA1, EA2, and EA3.

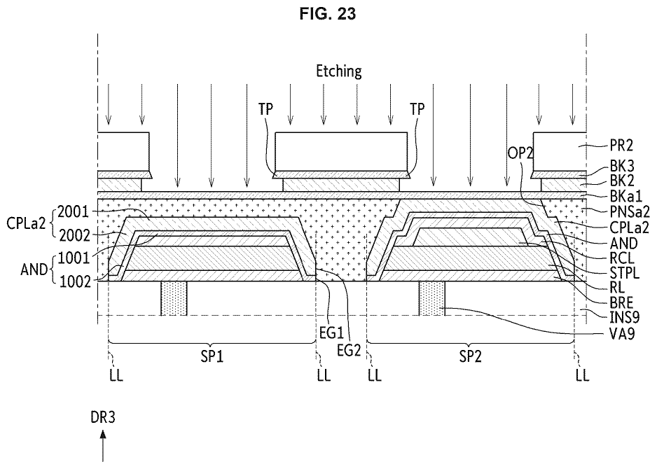

Next, as illustrated in FIG. 23, the third preliminary bank BKa3 and the second preliminary bank BKa2 may be patterned utilizing the second photoresist pattern PR2 as a mask (e.g., a second mask). For example, the third preliminary bank BKa3 and the second preliminary bank BKa2 may be etched and patterned by an etching process utilizing the second photoresist pattern PR2 as a mask (e.g., a second mask), thereby forming or providing the third bank BK3 and the second bank BK2. In this case, the second preliminary bank BKa2 under the third preliminary bank BKa3 may have an etching rate greater than the etching rate of the third preliminary bank BKa3, so that (e.g., such that) the second preliminary bank BKa2 may be etched faster than the third preliminary bank BKa3 during the etching process. Accordingly, after the etching (e.g., over etching) is completed, as illustrated in FIG. 23, the area of the second bank BK2 may become smaller than the area of the third bank BK3. Therefore, the structure including the second bank BK2 and the third bank BK3 may have a shape of an undercut having the tip TP. As described in one or more embodiments, the second preliminary bank BKa2 and the third preliminary bank BKa3 may be patterned utilizing the second photoresist pattern PR2 as a mask (e.g., a second mask), thereby exposing the first preliminary bank BKa1.

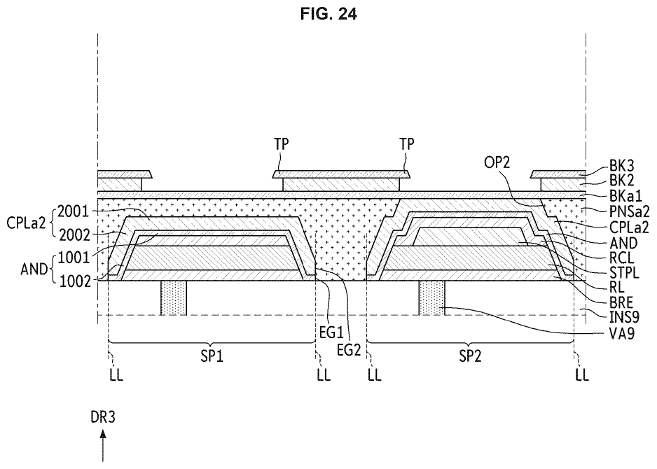

Thereafter, as illustrated in FIG. 24, after the etching process is completed, the second photoresist pattern PR2 may be removed.

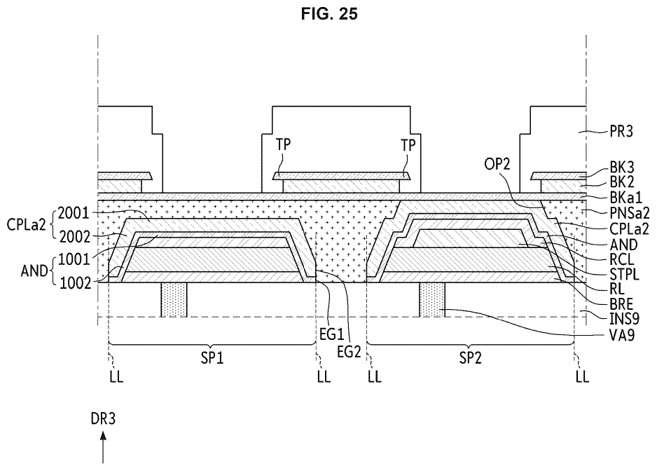

Next, as illustrated in FIG. 25, a third photoresist pattern PR3 may be formed or provided on the first preliminary bank BKa1 and the third bank BK3. For example, the third photoresist pattern PR3 may be formed or provided on the first preliminary bank BKa1 and the third bank BK3 to overlap each of the emission areas EA1, EA2, and EA3.

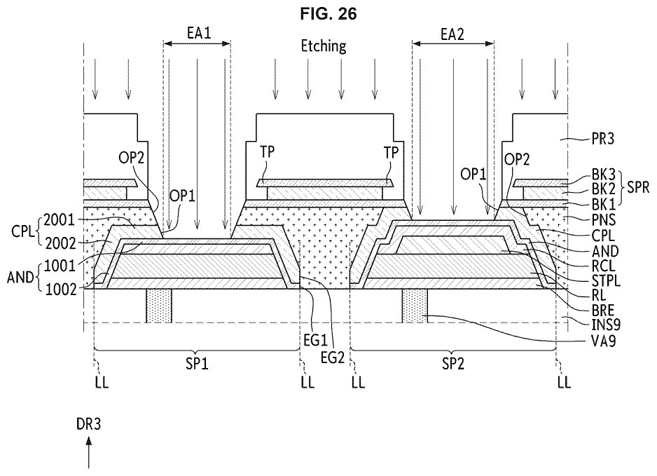

Next, as illustrated in FIG. 26, the first preliminary bank BKa1, the second preliminary planarization layer PNSa2, and the second preliminary capping layer CPLa2 may be patterned utilizing the third photoresist pattern PR3 as a mask (e.g., a third mask). For example, the first preliminary bank BKa1, the second preliminary planarization layer PNSa2, and the second preliminary capping layer CPLa2 may be etched and patterned by an etching process utilizing the third photoresist pattern PR3 as a mask (e.g., a third mask), thereby forming or providing the capping layer CPL, the planarization layer PNS, and the first bank BK1. For example, the capping layer CPL having the first opening OP1 that defines the first emission area EA1, the second emission area EA2, and the third emission area EA3 may be formed or provided, and the planarization layer PNS having the second opening OP2 overlapping the first opening OP1 may be formed or provided. Accordingly, the first electrode AND may be exposed for each of the sub-pixel areas SP1, SP2, and SP3 through the first opening OP1 and the second opening OP2. Thereafter, the third photoresist pattern PR3 may be removed.

Next, as illustrated in FIG. 9, the light emitting stack layer IL may be formed or provided on the first electrodes AND, the capping layer CPL, and the separator SPR, the second electrode CAT may be formed or provided on the light emitting stack layer IL, and the encapsulation layer TFE may be formed or provided on the second electrode CAT. Herein, the light emitting stack layer IL may be separated for each of the sub-pixel areas SP1, SP2, and SP3 by the separator SPR.

The display device 10 according to one or more embodiments may be applied to one or more suitable electronic devices. An electronic device according to one or more embodiments may include the display device 10 as described in one or more embodiments and may further include, in addition to the display device 10, a module or device having other additional functions.

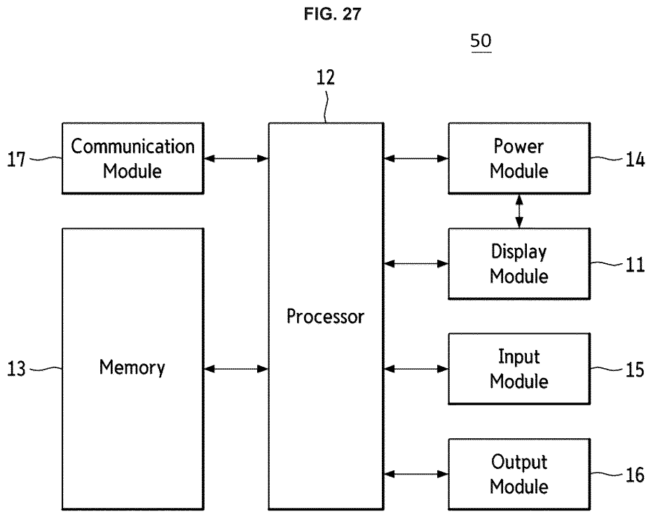

FIG. 27 is a block diagram of an electronic device according to one or more embodiments. Referring to FIG. 27, an electronic device 50 according to one or more embodiments may include a display module 11, a processor 12, a memory 13, and a power module 14. The electronic device 50 may further include an input module 15, a non-visual output module 16, and/or a communication module 17.

The electronic device 50 may output one or more suitable information in the form of images through the display module 11. If (e.g., when) the processor 12 executes an application stored in the memory 13, image information provided by the application may be provided to a user through the display module 11. The power module 14 may include a power supply module, such as a power adapter and/or a battery device, and a power conversion module that converts the power supplied by the power supply module to generate the power for the operation of the electronic device 50. The input module 15 may provide input information to the processor 12 and/or the display module 11. The non-visual output module 16 may serve to receive information other than images, such as sound, haptics, luminescence, and/or the like, sent from the processor 12, and provide it to the user. The communication module 17 may be a module responsible for the transmission and reception of information between the electronic device 50 and an external device and may include a receiver and a transmitter.

At least one selected from among the respective components of the electronic device 50 as described in one or more embodiments may be included in the display device according to one or more embodiments. Further, one or more of individual modules functionally included in one module may be included in the display device and one or more of others may be provided separately from the display device. For example, the display device may include the display module 11, whereas the processor 12, the memory 13, and the power module 14 may be provided in the form of other devices in the electronic device 50, other than the display device.

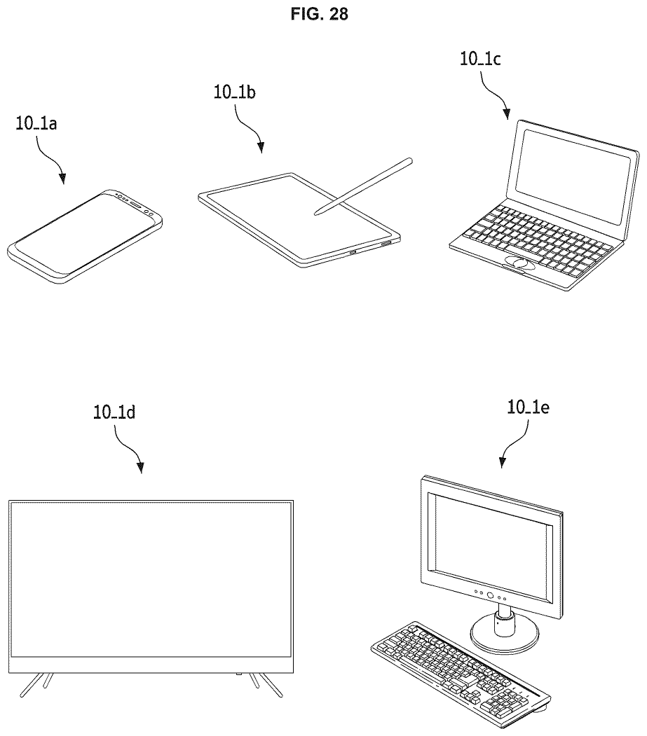

FIGS. 28, 29, and 30 are schematic diagrams illustrating electronic devices according to one or more embodiments. FIGS. 28 to 30 illustrate examples of one or more suitable electronic devices to which the display device 10 according to one or more embodiments are applied.

FIG. 28 illustrates a smartphone 10_1a, a tablet PC 10_1b, a laptop 10_1c, a TV 10_1d, and a desk monitor 10_1e as examples of electronic devices.

The smartphone 10_1a may include a communication module and an input module, such as a touch sensor and/or the like, in addition to the display module 11. The smartphone 10_1a may process the information received through the communication module or input module and display the processed information through the display module of the display device.

Each of the tablet PC 10_1b, the laptop 10_1c, the TV 10_1d, and the desk monitor 10_1e may include a display and an input module, similarly to the smartphone 10_1a, and may further include a communication module in one or more suitable cases.

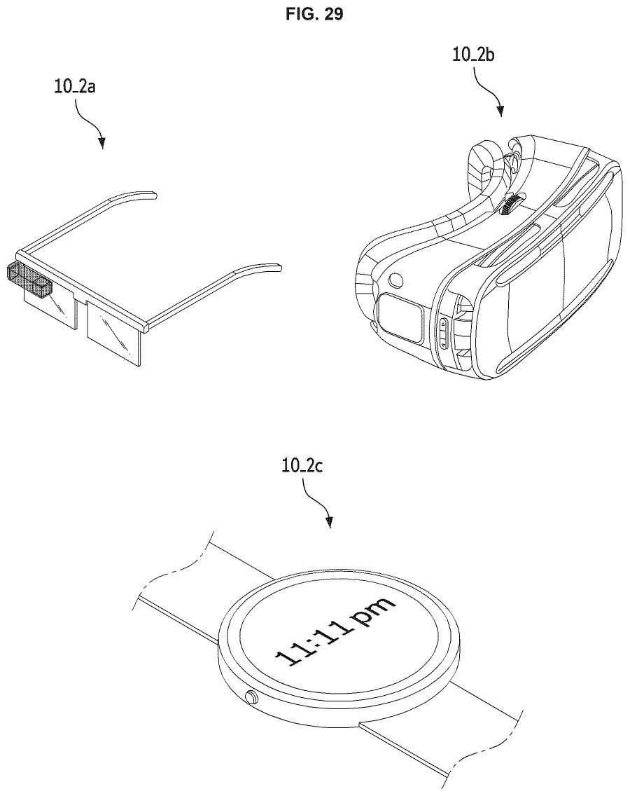

FIG. 29 illustrates a case in which an electronic device including a display module is applied to a wearable electronic device. The wearable electronic device may be smart glasses 10_2a, a head mounted display 10_2b, a smart watch 10_2c, and/or the like.

The smart glasses 10_2a and the head mounted display 10_2b may include a display module that outputs a display image and a reflector that reflects the outputted display image to provide it to the user's eyes, thereby providing the user with a virtual reality screen and/or an augmented reality screen.

The smart watch 10_2c may include a biometric sensor as an input device and may provide biometric information recognized through the biometric sensor to the user through a display module.

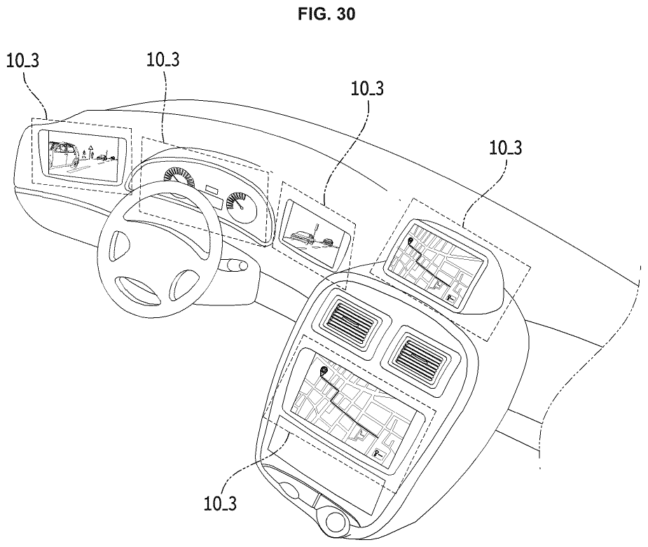

FIG. 30 illustrates a case in which an electronic device including a display module is applied to a vehicle. For example, an electronic device 10_3 may be applied to a dashboard and/or a center fascia of a vehicle or to a center information display (CID) placed in the dashboard of the vehicle or a room mirror display that replaces a side mirror.

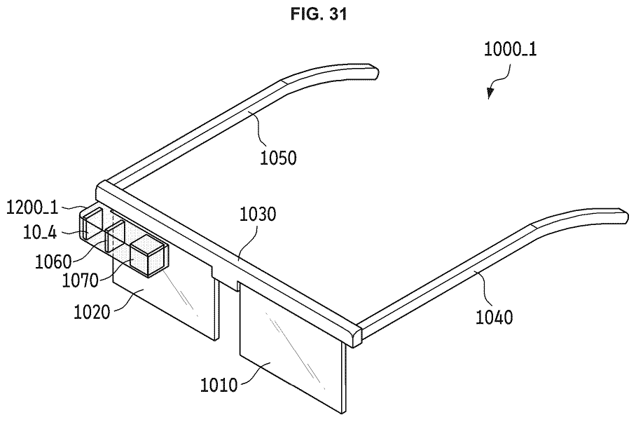

FIG. 31 is a perspective view illustrating a head mounted display according to one or more embodiments. For example, FIG. 31 may be a configuration or arrangement diagram of the smart glasses 10_2a of FIG. 29.

Referring to FIG. 31, a head mounted display 1000_1 according to one or more embodiments may be an eyeglasses-type or kind display device in which a display device housing 1200_1 is implemented in a lightweight and compact manner. The head mounted display 1000_1 according to one or more embodiments may include a display device 10_4, a left eye lens 1010, a right eye lens 1020, a support frame 1030, temples 1040 and 1050, an optical member 1060 (e.g., a lens), an optical path changing member 1070 (e.g., a mirror), and the display device housing 1200_1.

The display device housing 1200_1 may include the display device 10_4, the optical member 1060, and the optical path changing member 1070. The image displayed on the display device 10_4 may be magnified by the optical member 1060 and may be provided to the user's right eye through the right eye lens 1020 after the optical path is changed by the optical path changing member 1070. As a result, the user may view an augmented reality image, through the right eye, in which a virtual image displayed on the display device 10_4 and a real image seen through the right eye lens 1020 are combined.

FIG. 31 illustrates that the display device housing 1200_1 is located or provided at the right end of the support frame 1030, but embodiments of the present disclosure are not limited thereto. For example, the display device housing 1200_1 may be located or provided at the left end of the support frame 1030, and in this case, the image of the display device 10_4 may be provided to the user's left eye. In one or more embodiments, the display device housing 1200_1 may be located or provided at both (e.g., simultaneously) the left end and the right end of the support frame 1030, and in this case, the user may view the image displayed on the display device 10_4 through both (e.g., simultaneously) the left eye and the right eye.

While the subject matter of the present disclosure has been described in connection with what is presently considered to be practical example embodiments, it is to be understood that the present disclosure is not limited to the disclosed embodiments, but, in one or more embodiments, is intended to cover one or more suitable modifications and equivalent arrangements included within the spirit and scope of the appended claims and equivalents thereof. It therefore will be understood that one or more embodiments described herein are just illustrative but not limitative in all aspects.

What is claimed is:

1. A display device comprising:
a substrate comprising a first sub-pixel area and a second sub-pixel area;
a reflective electrode in the first sub-pixel area and the second sub-pixel area that are on the substrate;
a first electrode on the substrate to be around the reflective electrode;
a capping layer provided on the first electrode and having a first opening defined in the capping layer to overlap the first electrode;
a planarization layer provided on the capping layer and having a second opening defined in the planarization layer to overlap the first opening;
a light emitting stack layer on the first electrode; and
a second electrode on the light emitting stack layer,
wherein the first electrode comprises an upper electrode portion on a top surface of the reflective electrode and a side electrode portion extending from the upper electrode portion to the substrate and provided on a side surface of the reflective electrode,
the capping layer comprises an upper capping portion on the upper electrode portion and a side capping portion on the side electrode portion,
the side electrode portion in the first sub-pixel area is disconnected from the side electrode portion in the second sub-pixel area, and
the side capping portion in the first sub-pixel area is disconnected from the side capping portion in the second sub-pixel area.

2. The display device as claimed in claim 1, wherein a thickness of the side electrode portion is less than a thickness of the upper electrode portion.

3. The display device as claimed in claim 1, wherein a disconnected surface of the side electrode portion and a disconnected surface of the side capping portion are provided within one plane.

4. The display device as claimed in claim 1, wherein a disconnected surface of the side electrode portion and a disconnected surface of the side capping portion are in contact with the planarization layer.

5. The display device as claimed in claim 1, wherein the first opening of the capping layer is provided to overlap the upper electrode portion.

6. The display device as claimed in claim 1, further comprising a resonance control layer between the reflective electrode and the upper electrode portion,
wherein the side electrode portion is further provided on a side surface of the resonance control layer.

7. The display device as claimed in claim 6, further comprising a step layer between the reflective electrode and the resonance control layer in one selected from the first sub-pixel area and the second sub-pixel area.

8. The display device as claimed in claim 6, wherein the resonance control layer in the first sub-pixel area and the resonance control layer in the second sub-pixel area have different heights.

9. The display device as claimed in claim 1, further comprising a barrier electrode between the substrate and the reflective electrode,
wherein the side electrode portion is further provided on a side surface of the barrier electrode.

10. The display device as claimed in claim 1, further comprising:
a separator on the planarization layer; and
the light emitting stack layer on the separator,
wherein at least one or more of a plurality of light emitting layers in the light emitting stack layer on the separator are disconnected from the light emitting stack layer on the first electrode.

11. The display device as claimed in claim 10, wherein the separator comprises a lower bank and an upper bank on the lower bank, and
in a direction parallel to the substrate, an edge of the upper bank extends toward the first opening of the capping layer while passing through an edge of the lower bank.

12. An electronic device comprising:
a display device having a resolution of 4,000 PPI or higher;
an optical member outside the display device to control a path of light emitted from the display device; and
a case to accommodate the display device and the optical member,
wherein the display device comprises:
a substrate comprising a first sub-pixel area and a second sub-pixel area;
a reflective electrode in the first sub-pixel area and the second sub-pixel area that are on the substrate;
a first electrode on the substrate to be around the reflective electrode;
a capping layer provided on the first electrode and having a first opening defined in the capping layer to overlap the first electrode;
a planarization layer provided on the capping layer and having a second opening defined in the planarization layer to overlap the first opening;
a light emitting stack layer on the first electrode; and
a second electrode on the light emitting stack layer,
wherein the first electrode comprises an upper electrode portion on a top surface of the reflective electrode and a side electrode portion extending from the upper electrode portion to the substrate and provided on a side surface of the reflective electrode,
the side electrode portion in the first sub-pixel area is disconnected from the side electrode portion in the second sub-pixel area, and
the side capping portion in the first sub-pixel area is disconnected from the side capping portion in the second sub-pixel area.

13. The electronic device as claimed in claim 12, wherein the display device comprises an active area that implements an image and a non-active area that is outside the active area and does not implement the image or an other image, and
a maximum width of the active area is 1.5 inches or less.

14. The electronic device as claimed in claim 12, wherein the optical member comprises at least one of a lens or a mirror.

15. The electronic device as claimed in claim 12, wherein the electronic device is a wearable device comprising a head mounted display, smart glasses, or a smart watch.

16. A method for fabricating a display device, comprising:
preparing a substrate having an insulating layer and a via electrode penetrating the insulating layer on the substrate;
providing a reflective electrode and a resonance control layer that are sequentially stacked on the via electrode;
providing a first preliminary electrode on the insulating layer to be around the reflective electrode and the resonance control layer;
providing a first preliminary capping layer on the first preliminary electrode;
providing a first photoresist pattern on the first preliminary capping layer; and
etching the first preliminary capping layer and the first preliminary electrode together utilizing the first photoresist pattern as a first mask to provide a second preliminary capping layer and a first electrode, respectively, and exposing a part of the insulating layer.

17. The method as claimed in claim 16, wherein an etched surface of the second preliminary capping layer provided by the etching and an etched surface of the first electrode are provided within one plane.

18. The method as claimed in claim 16, further comprising:
removing the first photoresist pattern;
providing a first preliminary planarization layer on the insulating layer to cover the second preliminary capping layer;
providing a second preliminary planarization layer by polishing a surface of the first preliminary planarization layer until the second preliminary capping layer is exposed;
sequentially stacking a first preliminary bank, a second preliminary bank, and a third preliminary bank on the second preliminary planarization layer;
providing a second photoresist pattern on the third preliminary bank;
etching the third preliminary bank and the second preliminary bank utilizing the second photoresist pattern as a second mask to provide a third bank and a second bank, respectively, and exposing a part of the first preliminary bank; and
removing the second photoresist pattern.

19. The method as claimed in claim 18, wherein in the etching of the third preliminary bank and the second preliminary bank, the second preliminary bank has a higher etching rate than the third preliminary bank.

20. The method as claimed in claim 19, further comprising:
providing a third photoresist pattern on the first preliminary bank to be around the third bank and the second bank;
etching the first preliminary bank and the second preliminary capping layer utilizing the third photoresist pattern as a third mask to provide a first bank and a capping layer, respectively, and exposing a part of the first electrode through an opening of the capping layer provided by the etching;
removing the third photoresist pattern;
providing a light emitting stack layer on the first electrode and the third bank; and
providing a second electrode on the light emitting stack layer.
